(19) United States
(12) Patent Application Publication
(10) Pub. No.: US 2009/0045466 A1
(43) Pub. Date: Feb. 19, 2009

(54) SEMICONDUCTOR DEVICE

(75) Inventor: Hidetatsu Nakamura, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: NEC CORPORATION, Tokyo (JP)

(21) Appl. No.: 12/067,619

(22) PCT Filed: Sep. 13, 2006
(86) PCT No.: PCT/JP2006/318140

§ 371 Date: Mar. 20, 2008

(30) Foreign Application Priority Data
Sep. 21, 2005 (JP) 2005-273117

(51) Int. Cl. H01L 27/092; H01L 29/78

(52) U.S. Cl. 257/369; 257/288; 257/E29.255; 257/E27.062

(57) ABSTRACT

There are accomplished nMOSFET and pMOSFET both having high mobility, by optimizing stress and location of a film existing around a gate electrode such that high stress acts on a channel. In nMOSFET, a first film having compressive stress is formed on a gate electrode, and a second film having tensile stress is formed covering a gate electrode, a sidewall spacer of a gate electrode, and source/drain regions therewith. In pMOSFET, a film having tensile stress is formed on the gate electrode in place of the first film, and a film having compressive stress is formed in place of the second film.

### BACKGROUND OF THE INVENTION

1. Field of the Invention

The invention relates to a semiconductor device, and more particularly to both an n-channel or p-channel type MOSFET semiconductor device in which distortion is applied to a channel region, and a CMOSFET semiconductor device including both of n-channel and p-channel type MOSFETs.

2. Background Art

Recently, performance required to LSI becomes higher and higher as a data communication device develops, and thus, a transistor capable of operating at a higher rate is now being developed.

A higher rate in operation of a transistor has been conventionally accomplished by designing a transistor to have a smaller structure. However, it is now quite difficult to shorten a gate length due to the limit of lithography process, and to form a gate insulating film thin due to physical factors. Accordingly, there is a need for new techniques to enhance performance of a transistor, other than designing a transistor to have a smaller structure.

As one of such new techniques, there has been suggested a process (piezo-resistance effect) of distorting a channel by applying stress thereto for enhancing mobility.

When a channel is distorted by applying tensile stress thereto in a direction parallel to the channel, a mobility of electrons is enhanced, and a mobility of holes is deteriorated. In contrast, when a channel is distorted by applying compressive stress thereto in a direction parallel to the channel, a mobility of electrons is deteriorated, and a mobility of holes is enhanced. Several attempts have been made to enhance performance of MOSFET by virtue of the above-mentioned phenomenon.

For instance, Japanese Patent Application Publication No. 2002-198368 has suggested a method of enhancing performance of an n-channel type MOSFET (hereinafter, referred to as “nMOSFET”), in which a stopper film used when a contact hole is formed is comprised of a silicon nitride film, and the silicon nitride film is caused to have high tensile stress to thereby distort a channel, resulting in enhancement in a mobility of electrons.

Japanese Patent Application Publication No. 2003-86708 has suggested a method of enhancing performance of both of an nMOSFET and a p-channel type MOSFET (hereinafter, referred to as “pMOSFET”), in which an nMOSFET is covered with a silicon nitride film having tensile stress, and a pMOSFET is covered with a silicon nitride film having compressive stress, thereby enhancing a mobility of carriers.

International Publication WO2002/043151 (PCT/JP2001/005633) has suggested a semiconductor device including an n-channel type field effect transistor having a channel in a first region at a principal surface of a semiconductor substrate, and a p-channel type field effect transistor having a channel in a second region different from the first region in the principal surface of the semiconductor substrate, wherein inner stress generated in the channel of the n-channel type field effect transistor is different from inner stress generated in the channel of the p-channel type field effect transistor.

Japanese Patent Application Publication No. 2003-60076 has suggested a semiconductor device including a n-channel MOSFET and a p-channel MOSFET both formed on a silicon substrate, characterized by a first nitride film having intrinsic tensile stress and covering the n-channel MOSFET therewith, and a second nitride film having intrinsic compressive stress and covering the p-channel MOSFET therewith.

However, if a silicon nitride film is used as it is as a stress-having film as suggested in the above-mentioned Publications, it is quite difficult to apply high stress (distortion) to a channel.

Hereinbelow is explained the reason.

FIG. 31 is a cross-sectional view of a MOSFET covered with a silicon nitride film 109.

The illustrated MOSFET is comprised of a silicon substrate 101, device separation regions 102 formed at a surface of the silicon substrate 101, a gate insulating film 106 formed on a surface of the silicon substrate 101 in a region divided by the device separation regions 102, a gate electrode 107 formed on the gate insulating film 106, a sidewall spacer 108 covering sidewalls of the gate insulating film 106 and the gate electrode 107 therewith, and impurity-diffusing layers 103 and silicide layers 105 both formed at a surface of the silicon substrate 101 and making source/drain regions.

As illustrated in FIG. 31, the MOSFET is entirely covered with a silicon nitride film 109.

FIG. 32 is a graph showing stresses applied to a channel in portions of the silicon nitride film 109.

In FIG. 32, as the above-mentioned portions of the silicon nitride film 109, there are selected three portions, specifically, a portion A indicating a top of the gate electrode 107, a portion B indicating a side of the gate electrode 107, and a portion C indicating a surface of the source/drain regions.

A silicon nitride film having tensile stress was selected as the silicon nitride film 109.

A positive area in an axis of ordinates in the graph (FIG. 32) indicates tensile stress (accordingly, a negative area in the axis of ordinates indicates compressive stress).

As is obvious in view of FIG. 32, stress is applied to a channel principally by a portion of the silicon nitride film 109 (the portion C) disposed on the source/drain regions, a portion of the silicon nitride film 109 (the portion A) disposed on the gate electrode 107 exerts stress on a channel so as to cancel the firstly mentioned stress. A portion of the silicon nitride film 109 (the portion B) disposed at a side of the gate electrode 107 applies quite smaller stress to a channel than stress exerted on a channel by a portion of the silicon nitride film 109 (the portion C) disposed on the source/drain regions.

As a result, there is caused a problem that the stresses cancel one another, and accordingly, quite small stress is actually applied to a channel.

The same problem as mentioned above is caused when the silicon nitride film 109 is comprised of a film having compressive stress.

### SUMMARY OF THE INVENTION

In view of the above-mentioned problems in the related nMOSFET and pMOSFET, it is an exemplary object of the present invention to provide a semiconductor device which is capable of enhancing mobility of carriers to thereby enhance performances of nMOSFET and pMOSFET by optimizing stress and location of a film existing around a gate electrode such that high stress (distortion) acts on a channel.

In an exemplary aspect, the present invention provides a semiconductor device including an n-channel type MOSFET, wherein the semiconductor device includes a first stress-having film being formed on a gate electrode of the n-channel type MOSFET, and locally having compressive stress.

In an exemplary aspect, the present invention further provides a semiconductor device including a p-channel type MOSFET, wherein the semiconductor device includes a second stress-having film being formed on a gate electrode of the p-channel type MOSFET, and locally having tensile stress.

In an exemplary aspect, the present invention further provides a semiconductor device including an n-channel type MOSFET and a p-channel type MOSFET, wherein the semiconductor device includes a first stress-having film being formed on a gate electrode of the n-channel type MOSFET, and locally having compressive stress, and a second stress-having film being formed on a gate electrode of the p-channel type MOSFET, and locally having tensile stress.

It is preferable that the semiconductor device further includes a third stress-having film covering the n-channel type MOSFET therewith, and having tensile stress.

It is preferable that the semiconductor device further includes a fourth stress-having film covering the p-channel type MOSFET therewith, and having compressive stress.

In an exemplary aspect, the present invention further provides a semiconductor device including an n-channel type MOSFET, wherein the semiconductor device includes a first stress-having film being formed on a gate electrode of the n-channel type MOSFET, and having compressive stress, and a third stress-having film being formed on source/drain regions of the n-channel type MOSFET, having almost the same height as that of the first stress-having film, and having tensile stress.

In an exemplary aspect, the present invention further provides a semiconductor device including a p-channel type MOSFET, wherein the semiconductor device includes a second stress-having film being formed on a gate electrode of the p-channel type MOSFET, and having tensile stress, and a seventh stress-having film being formed on source/drain regions of the p-channel type MOSFET, having almost the same height as that of the second stress-having film, and having compressive stress.

In an exemplary aspect, the present invention further provides a semiconductor device including an n-channel type MOSFET and a p-channel type MOSFET, wherein the semiconductor device includes a first stress-having film being formed on a gate electrode of the n-channel type MOSFET, and having compressive stress, a third stress-having film being formed on source/drain regions of the n-channel type MOSFET, having almost the same height as that of the first stress-having film, and having tensile stress, a second stress-having film being formed on a gate electrode of the p-channel type MOSFET, and having tensile stress, and a seventh stress-having film being formed on source/drain regions of the p-channel type MOSFET, having almost the same height as that of the second stress-having film, and having compressive stress.

In an exemplary aspect, the present invention further provides a semiconductor device including an n-channel type MOSFET, wherein the semiconductor device includes a fifth stress-having film being formed on source/drain regions of the n-channel type MOSFET, having almost the same height as that of a gate electrode of the n-channel type MOSFET, and having tensile stress, and a sixth stress-having film being formed entirely on both a gate electrode of the n-channel type MOSFET and the fifth stress-having film, and having compressive stress.

In an exemplary aspect, the present invention further provides a semiconductor device including a p-channel type MOSFET, wherein the semiconductor device includes a seventh stress-having film being formed on source/drain regions of the p-channel type MOSFET, having almost the same height as that of a gate electrode of the p-channel type MOSFET, and having compressive stress, and an eighth stress-having film being formed entirely on both a gate electrode of the p-channel type MOSFET and the seventh stress-having film, and having tensile stress.

In an exemplary aspect, the present invention further provides a semiconductor device including an n-channel type MOSFET and a p-channel type MOSFET, wherein the semiconductor device includes a fifth stress-having film being formed on source/drain regions of the n-channel type MOSFET, having almost the same height as that of a gate electrode of the n-channel type MOSFET, and having tensile stress, a sixth stress-having film being formed entirely on both a gate electrode of the n-channel type MOSFET and the fifth stress-having film, and having compressive stress, a seventh stress-having film being formed on source/drain regions of the p-channel type MOSFET, having almost the same height as that of a gate electrode of the p-channel type MOSFET, and having compressive stress, and an eighth stress-having film being formed entirely on both a gate electrode of the p-channel type MOSFET and the seventh stress-having film, and having tensile stress.

In an exemplary aspect, the present invention further provides a semiconductor device including an n-channel type MOSFET, wherein the semiconductor device includes a fifth stress-having film being formed on source/drain regions of the n-channel type MOSFET, having almost the same height as that of a gate electrode of the n-channel type MOSFET, and having tensile stress, and a sixth stress-having film being formed on a gate electrode of the n-channel type MOSFET, and having compressive stress.

In an exemplary aspect, the present invention further provides a semiconductor device including a p-channel type MOSFET, wherein the semiconductor device includes a seventh stress-having film being formed on source/drain regions of the p-channel type MOSFET, having almost the same height as that of a gate electrode of the p-channel type MOSFET, and having compressive stress, and an eighth stress-having film being formed on a gate electrode of the p-channel type MOSFET, and having tensile stress.

In an exemplary aspect, the present invention further provides a semiconductor device including an n-channel type MOSFET and a p-channel type MOSFET, wherein the semiconductor device includes a fifth stress-having film being formed on source/drain regions of the n-channel type MOSFET, having almost the same height as that of a gate electrode of the n-channel type MOSFET, and having tensile stress, a sixth stress-having film being formed on a gate electrode of the n-channel type MOSFET, and having compressive stress, a seventh stress-having film being formed on source/drain regions of the p-channel type MOSFET, having almost the same height as that of a gate electrode of the p-channel type MOSFET, and having compressive stress, and an eighth stress-having film being formed on a gate electrode of the p-channel type MOSFET, and having tensile stress.

In an exemplary aspect, the present invention further provides a semiconductor device including an n-channel type MOSFET and a p-channel type MOSFET, wherein the semiconductor device includes a first stress-having film being formed on a gate electrode of the n-channel type MOSFET, and locally having compressive stress, a second stress-having film being formed on a gate electrode of the p-channel type MOSFET, and locally having tensile stress, a third stress-having film covering the n-channel type MOSFET therewith, and having tensile stress, and a fourth stress-having film covering the p-channel type MOSFET therewith, and having compressive stress.

In an exemplary aspect, the present invention further provides a semiconductor device including an n-channel type MOSFET and a p-channel type MOSFET, wherein the semiconductor device includes a first stress-having film being formed on both a gate electrode of the n-channel type MOSFET and a gate electrode of the p-channel type MOSFET, and locally having compressive stress, a third stress-having film covering the n-channel type MOSFET therewith, and having tensile stress, and a fourth stress-having film covering the p-channel type MOSFET therewith, and having compressive stress.

In an exemplary aspect, the present invention further provides a semiconductor device including an n-channel type MOSFET and a p-channel type MOSFET, wherein the semiconductor device includes a second stress-having film being formed on both a gate electrode of the n-channel type MOSFET and a gate electrode of the p-channel type MOSFET, and locally having tensile stress, a third stress-having film covering the n-channel type MOSFET therewith, and having tensile stress, and a fourth stress-having film covering the p-channel type MOSFET therewith, and having compressive stress.

In an exemplary aspect, the present invention further provides a semiconductor device including an n-channel type MOSFET and a p-channel type MOSFET, wherein the semiconductor device includes a first stress-having film being formed on a gate electrode of the n-channel type MOSFET, and locally having compressive stress, a second stress-having film being formed on a gate electrode of the p-channel type MOSFET, and locally having tensile stress, and a third stress-having film covering the n-channel type MOSFET and the p-channel type MOSFET therewith, and having tensile stress.

In an exemplary aspect, the present invention further provides a semiconductor device including an n-channel type MOSFET and a p-channel type MOSFET, wherein the semiconductor device includes a first stress-having film being formed on a gate electrode of the n-channel type MOSFET, and locally having compressive stress, a second stress-having film being formed on a gate electrode of the p-channel type MOSFET, and locally having tensile stress, and a fourth stress-having film covering the n-channel type MOSFET and the p-channel type MOSFET therewith, and having compressive stress.

It is preferable that at least one of the third stress-having film and the fourth stress-having film has a portion on the gate electrode in which stress is relaxed.

It is preferable that at least one of the third stress-having film and the fourth stress-having film is partially cut out on the gate electrode.

It is preferable that the third stress-having film or the fourth stress-having film covering source/drain regions of the n-channel type MOSFET or the p-channel type MOSFET has such a thickness that a surface of the third stress-having film or the fourth stress-having film is on a level with a surface of the first stress-having film or the second stress-having film.

In an exemplary aspect, the present invention further provides a semiconductor device including an n-channel type MOSFET and a p-channel type MOSFET, wherein the semiconductor device includes a fifth stress-having film being formed on both source/drain regions of the n-channel type MOSFET and source/drain regions of the p-channel type MOSFET, having almost the same height as that of gate electrodes of the n-channel type MOSFET and the p-channel type MOSFET, and having tensile stress, a sixth stress-having film being formed on a gate electrode of the n-channel type MOSFET, and having compressive stress, and an eighth stress-having film being formed on a gate electrode of the p-channel type MOSFET, and having tensile stress.

In an exemplary aspect, the present invention further provides a semiconductor device including an n-channel type MOSFET and a p-channel type MOSFET, wherein the semiconductor device includes a seventh stress-having film being formed on both source/drain regions of the n-channel type MOSFET and source/drain regions of the p-channel type MOSFET, having almost the same height as that of gate electrodes of the n-channel type MOSFET and the p-channel type MOSFET, and having compressive stress, a sixth stress-having film being formed on a gate electrode of the n-channel type MOSFET, and having compressive stress, and an eighth stress-having film being formed on a gate electrode of the p-channel type MOSFET, and having tensile stress.

In an exemplary aspect, the present invention further provides a semiconductor device including an n-channel type MOSFET and a p-channel type MOSFET, wherein the semiconductor device includes a fifth stress-having film being formed on source/drain regions of the n-channel type MOSFET, having almost the same height as that of a gate electrode of the n-channel type MOSFET, and having tensile stress, a seventh stress-having film being formed on source/drain regions of the p-channel type MOSFET, having almost the same height as that of a gate electrode of the p-channel type MOSFET, and having compressive stress, and one of a sixth stress-having film and an eighth stress-having film, the sixth stress-having film being formed on both a gate electrode of the n-channel type MOSFET and a gate electrode of the p-channel type MOSFET, and having compressive stress, the eighth stress-having film being formed on both a gate electrode of the n-channel type MOSFET and a gate electrode of the p-channel type MOSFET, and having tensile stress.

In an exemplary aspect, the present invention further provides a semiconductor device including an n-channel type MOSFET and a p-channel type MOSFET, wherein the semiconductor device includes a fifth stress-having film being formed on both source/drain regions of the n-channel type MOSFET and source/drain regions of the p-channel type MOSFET, having almost the same height as that of gate electrodes of the n-channel type MOSFET and the p-channel type MOSFET, and having tensile stress, a sixth stress-having film covering the n-channel type MOSFET therewith and being formed on the fifth stress-having film, and having compressive stress, and an eighth stress-having film covering the p-channel type MOSFET therewith and being formed on the fifth stress-having film, and having tensile stress.

In an exemplary aspect, the present invention further provides a semiconductor device including an n-channel type MOSFET and a p-channel type MOSFET, wherein the semiconductor device includes a seventh stress-having film being formed on both source/drain regions of the n-channel type MOSFET and source/drain regions of the p-channel type MOSFET, having almost the same height as that of gate electrodes of the n-channel type MOSFET and the p-channel type MOSFET, and having compressive stress, a sixth stress-having film covering the n-channel type MOSFET therewith and being formed on the seventh stress-having film, and having compressive stress, and an eighth stress-having film covering the p-channel type MOSFET therewith and being formed on the seventh stress-having film, and having tensile stress.

In an exemplary aspect, the present invention further provides a semiconductor device including an n-channel type MOSFET and a p-channel type MOSFET, wherein the semiconductor device includes a fifth stress-having film being formed on source/drain regions of the n-channel type MOSFET, having almost the same height as that of a gate electrode of the n-channel type MOSFET, and having tensile stress, a seventh stress-having film being formed on source/drain regions of the p-channel type MOSFET, having almost the same height as that of a gate electrode of the p-channel type MOSFET, and having compressive stress, one of a sixth stress-having film and an eighth stress-having film, the sixth stress-having film covering both the n-channel type MOSFET and the p-channel type MOSFET therewith and being formed on both the fifth stress-having film and the seventh stress-having film, and having compressive stress, the eighth stress-having film covering both the n-channel type MOSFET and the p-channel type MOSFET therewith and being formed on the fifth stress-having film and the seventh stress-having film, and having tensile stress.

The semiconductor device may include, in place of the first stress-having film, a first electrically conductive stress-having film being formed at least partially on a gate electrode of the n-channel type MOSFET, and having compressive stress, for instance.

The semiconductor device may include, in place of the second stress-having film, a second electrically conductive stress-having film being formed at least partially on a gate electrode of the p-channel type MOSFET, and having tensile stress, for instance.

It is preferable that each of the first, second, sixth and eighth stress-having film contains at least one of silicide of carbon, oxygen or nitrogen, hydrogenated silicide of carbon, oxygen or nitrogen, oxide of aluminum, hafnium, tantalum, zirconium or silicon, and nitrogenated oxide of aluminum, hafnium, tantalum, zirconium or silicon.

It is preferable that the first or second electrically conductive stress-having film contains at least one of silicide containing one of cobalt, nickel and titanium, tungsten, aluminum, copper, and platinum.

It is preferable that at least one of the n-channel type MOSFET and the p-channel type MOSFET is formed on a substrate composed of one of silicon containing silicon and germanium therein, and silicon containing carbon therein.

The above and other objects and advantageous features of the present invention will be made apparent from the following description made with reference to the accompanying drawings, in which like reference characters designate the same or similar parts throughout the drawings.

### BRIEF DESCRIPTION OF THE DRAWINGS

FIG. 1 is a cross-sectional view of an n-channel type MOSFET in accordance with the first exemplary embodiment of the present invention.

FIG. 2 is a graph showing stress applied to a channel by the first stress-having film having compressive stress, and stress applied to a channel by a film having tensile stress (background art) in the case that the film having tensile stress is formed in place of the first stress-having film.

FIGS. 3A, 3B and 3C are cross-sectional views showing steps to be carried out in a method of fabricating an n-channel type MOSFET in accordance with the first exemplary embodiment of the present invention.

FIG. 4 is a cross-sectional view of an n-channel type MOSFET in accordance with a first variant of the first exemplary embodiment.

FIGS. 5A and 5B are cross-sectional views showing steps to be carried out in a method of fabricating an n-channel type MOSFET in accordance with the second exemplary embodiment of the present invention.

FIGS. 6A and 6B are cross-sectional views showing steps to be carried out in a method of fabricating an n-channel type MOSFET in accordance with a first variant of the second exemplary embodiment.

FIG. 7 is a cross-sectional view of an n-channel type MOSFET in accordance with a second variant of the second exemplary embodiment.

FIG. 8 is a cross-sectional view of an n-channel type MOSFET in accordance with a third variant of the second exemplary embodiment.

FIGS. 9A, 9B, 9C and 9D are cross-sectional views showing steps to be carried out in a method of fabricating an n-channel type MOSFET in accordance with the third exemplary embodiment of the present invention.

FIG. 10 is a cross-sectional view of an n-channel type MOSFET in accordance with a first variant of the third exemplary embodiment.

FIG. 11 is a cross-sectional view of a p-channel type MOSFET in accordance with the fourth exemplary embodiment of the present invention.

FIG. 12 is a cross-sectional view of a p-channel type MOSFET in accordance with the fifth exemplary embodiment of the present invention.

FIG. 13 is a cross-sectional view of a p-channel type MOSFET in accordance with a first variant of the fifth exemplary embodiment.

FIG. 14 is a cross-sectional view of a p-channel type MOSFET in accordance with the sixth exemplary embodiment of the present invention.

FIG. 15 is a cross-sectional view of a CMOSFET in accordance with the seventh exemplary embodiment of the present invention.

FIGS. 16A, 16B, 16C, 16D and 16E are cross-sectional views showing steps to be carried out in a method of fabricating a CMOSFET in accordance with the seventh exemplary embodiment of the present invention.

FIG. 17 is a cross-sectional view of a CMOSFET in accordance with a first variant of the seventh exemplary embodiment.

FIGS. 18A, 18B and 18C are cross-sectional views showing steps to be carried out in a method of fabricating a CMOSFET in accordance with the eighth exemplary embodiment of the present invention.

FIGS. 19D and 19E are cross-sectional views showing steps to be carried out in a method of fabricating a CMOSFET in accordance with the eighth exemplary embodiment of the present invention.

FIG. 20 is a cross-sectional view of a CMOSFET in accordance with a first variant of the eighth exemplary embodiment.

FIGS. 21A, 21B, 21C and 21D are cross-sectional views showing steps to be carried out in a method of fabricating a CMOSFET in accordance with the ninth exemplary embodiment of the present invention.

FIGS. 22E, 22F and 22G are cross-sectional views showing steps to be carried out in a method of fabricating a CMOSFET in accordance with the ninth exemplary embodiment of the present invention.

FIG. 23 is a cross-sectional view of a CMOSFET in accordance with the tenth exemplary embodiment of the present invention.

FIG. 24 is a cross-sectional view of a CMOSFET in accordance with the eleventh exemplary embodiment of the present invention.

FIG. 25 is a cross-sectional view of a CMOSFET in accordance with the twelfth exemplary embodiment of the present invention.

FIG. 26 is a cross-sectional view of a CMOSFET in accordance with the thirteenth exemplary embodiment of the present invention.

FIG. 27 is a cross-sectional view of a CMOSFET in accordance with the fourteenth exemplary embodiment of the present invention.

FIG. 28 is a cross-sectional view of a CMOSFET in accordance with the fifteenth exemplary embodiment of the present invention.

FIG. 29 is a cross-sectional view of a CMOSFET in accordance with the sixteenth exemplary embodiment of the present invention.

FIG. 30 is a cross-sectional view of a CMOSFET in accordance with the seventeenth exemplary embodiment of the present invention.

FIG. 31 is a cross-sectional view of a related MOSFET.

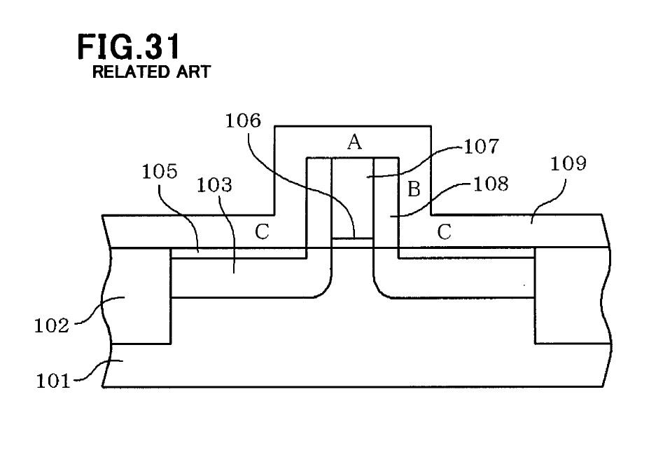

FIG. 32 is a graph showing stresses applied to a channel in portions of a silicon nitride film covering therewith the related MOSFET illustrated in FIG. 31.

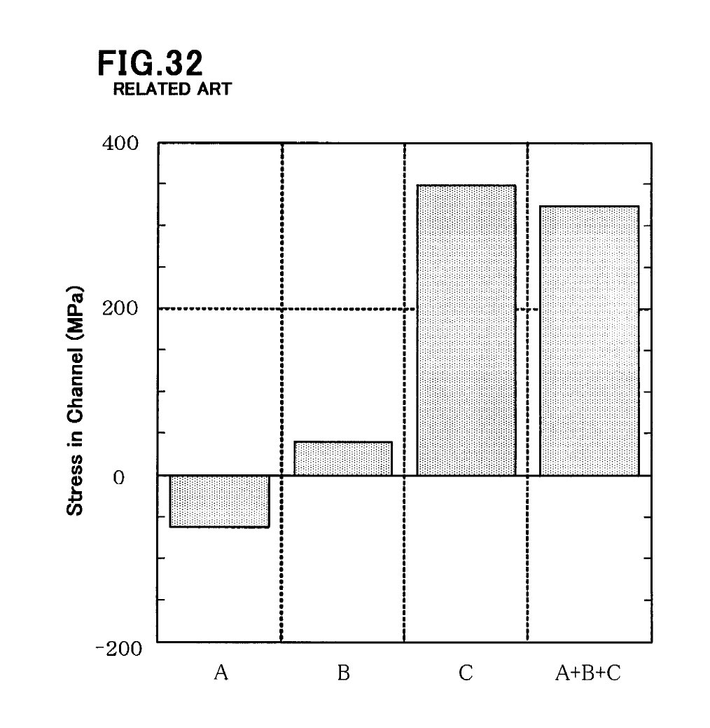

### DESCRIPTION OF THE EXEMPLARY EMBODIMENTS

Preferred exemplary embodiments in accordance with the present invention will be explained hereinbelow with reference to drawings.

### First Exemplary Embodiment

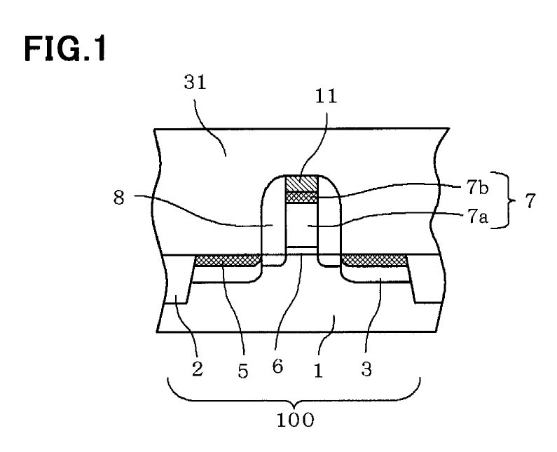

FIG. 1 is a cross-sectional view of an n-channel type field effect transistor (MOSFET) 100 in accordance with the first exemplary embodiment of the present invention.

The n-channel type MOSFET 100 in accordance with the first exemplary embodiment is comprised of a silicon substrate 1, device separation regions 2 formed at a surface of the silicon substrate 1, a gate insulating film 6 formed on a surface of the silicon substrate 1 in a region sandwiched between the device separation regions 2, a gate electrode 7 having a two-layered structure including a silicon film 7a and a silicide layer 7b both formed on the gate insulating film 6, n-type impurity diffusing layers 3 formed at a surface of the silicon substrate 1 and making source/drain regions, silicide layers 5 formed on the n-type impurity diffusing layers 3, a first stress-having film 11 being formed on the gate electrode 7 and having compressive stress, a sidewall spacer 8 covering sidewalls of the gate insulating film 6, the gate electrode 7 and the first stress-having film 11 therewith, and an interlayer insulating film 31 being formed entirely on the silicon substrate 1.

Hereinbelow is explained advantages presented by the n-channel type MOSFET 100 in accordance with the first exemplary embodiment.

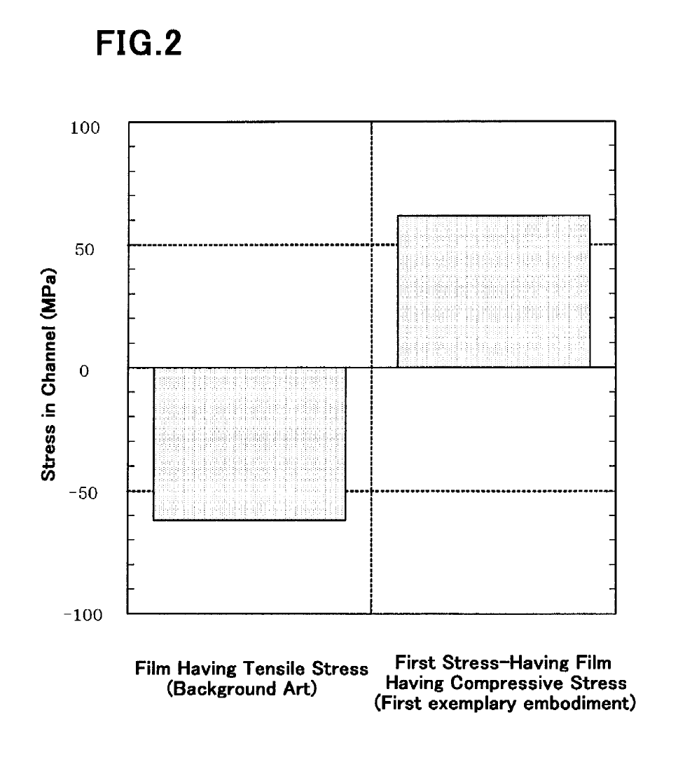

FIG. 2 is a graph showing stress applied to a channel by the first stress-having film 11 having compressive stress, and stress applied to a channel by a film having tensile stress (background art) in the case that the film having tensile stress is formed in place of the first stress-having film 11.

A zero-point in the axis of ordinates in FIG. 2 indicates that stress applied to a channel by a film is zero. Tensile stress is indicated as positive stress.

It is understood in view of FIG. 2 that higher tensile stress is applied to a channel in the n-channel type MOSFET 100 in accordance with the first exemplary embodiment than in the related transistor.

Thus, a channel is much distorted in a direction in which tensile stress is applied, and accordingly, mobility of electrons in a channel in the n-channel type MOSFET is much enhanced.

The advantages obtained by the first exemplary embodiment through the use of examples can be confirmed by the converged electron diffraction process, as suggested in Japanese Patent Application Publication No. 2000-9664, for instance. In this process, converges electrons are emitted into an example, and distortion is calculated from the resultant diffracted image. In accordance with the process, it is possible to measure distortion in a particular portion with spatial resolution of about 10 nanometers. By measuring distortion by the converged electron diffraction process in both the n-channel type MOSFET 100 in accordance with the first exemplary embodiment, and an example which is comprised of the n-channel type MOSFET 100 in accordance with the first exemplary embodiment, but out of which the first stress-having film 11 formed on the gate electrode 7 is removed, and comparing them with each other, it is possible to confirm the advantages to be obtained by the n-channel type MOSFET 100 in accordance with the first exemplary embodiment in an example level.

In the n-channel type MOSFET 100 in accordance with the first exemplary embodiment, it is preferable that a semiconductor substrate is composed of silicon or silicon containing germanium or carbon therein.

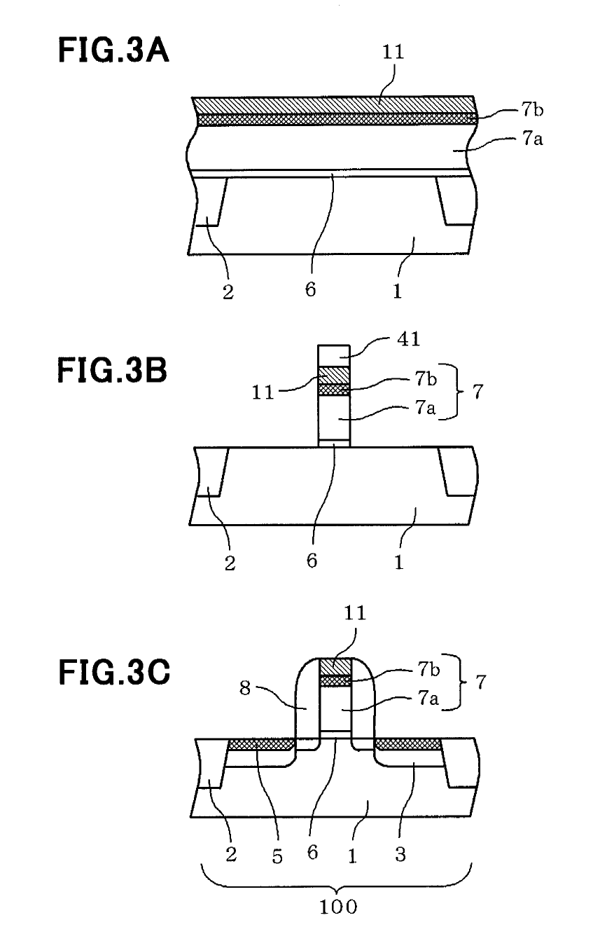

FIGS. 3A to 3C are cross-sectional views showing steps to be carried out in a method of fabricating the n-channel type MOSFET 100 in accordance with the first exemplary embodiment.

Hereinbelow is explained a method of fabricating the n-channel type MOSFET 100 in accordance with the first exemplary embodiment, with reference to FIGS. 3A to 3C.

First, similarly to a related MOSFET, the device separation regions 2 are formed at a surface of the silicon substrate 1.

For instance, the device separation regions 2 may be comprised of a silicon oxide film, a silicon nitride film, or a film having a multi-layered structure including a silicon oxide film and a silicon nitride film.

Then, as illustrated in FIG. 3A, the gate insulating film 6, the silicon film 7a, the silicide layer 7b, and the first stress-having film 11 having compressive stress are formed on a surface of the silicon substrate 1 in this order.

For instance, the gate insulating film 6 may be comprised of a silicon oxide film, a film having a high dielectric constant and containing, for instance, nitrogen, hafnium, aluminum, titanium, zirconium or tantalum, or a film having a multi-layered structure including a silicon oxide film and the above-mentioned film having a high dielectric constant.

For instance, the silicon film 7a may be comprised of a polysilicon film, an amorphous silicon film, or a film having a multi-layered structure including a polysilicon film and an amorphous silicon film.

For instance, the silicide layer 7b may be composed of silicide containing therein metal such as cobalt or nickel.

The first stress-having film 11 is comprised of an electrically insulating film having compressive stress. For instance, the first stress-having film 11 is comprised of a silicon nitride film formed by plasma-enhanced chemical vapor deposition.

The first stress-having film 11 may be composed of silicide containing one of carbon, oxygen and nitrogen, hydrogenated silicide containing one of carbon, oxygen and nitrogen, oxide containing aluminum, hafnium, tantalum, zirconium or silicon, or such oxide to which nitrogen or oxide nitride is added.

Then, resist is coated for the purpose of forming the gate electrode 7. Then, an unnecessary portion of the resist is removed by known photolithography to thereby form a resist film 41. Then, the first stress-having film 11, the silicide layer 7b, the silicon film 7a and the gate insulating film 6 are removed by dry etching in a portion not covered with the resist film 41 to thereby form the gate electrode 7. The structure at this stage is illustrated in FIG. 3B.

After the resist film 41 was removed, ions are implanted into the silicon substrate 1 to form the silicide layer 5 acting as shallow source/drain regions. A film is formed around the gate electrode 7 and is etched back to thereby form the sidewall spacer 8. Ions are implanted into the silicon substrate 1 to form the n-type impurity layer 3 acting as deep source/drain regions. Then, the silicon substrate 1 is annealed for activating the impurities to thereby complete the silicide layer 5 and the n-type impurity layer 3. The structure at this stage is illustrated in FIG. 3C.

For instance, the sidewall spacer 8 is comprised of a silicon oxide film, a silicon nitride film, or a film having a multi-layered structure including a silicon oxide film and a silicon nitride film.

For instance, the silicide layer 5 is comprised of a silicide film containing therein metal such as cobalt or nickel.

Then, the interlayer insulating film 31 is formed entirely on the silicon substrate 1. Thus, there is obtained the structure illustrated in FIG. 1.

Thereafter, a contact hole is formed, and then, a contact plug is formed in the contact hole. Then, necessary wires are arranged on the contact plug.

### First Variant of First Exemplary Embodiment

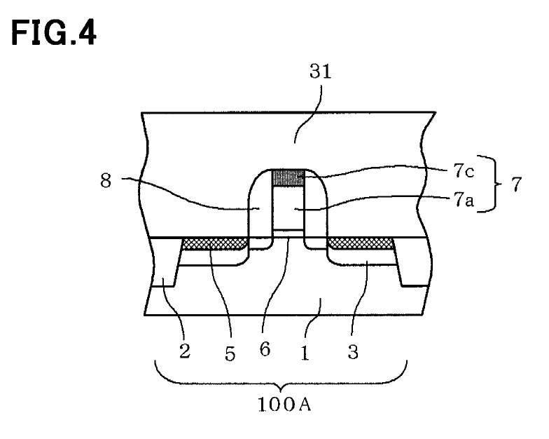

FIG. 4 is a cross-sectional view of an n-channel type MOSFET 100A in accordance with a first variant of the first exemplary embodiment.

As illustrated in FIG. 4, the n-channel type MOSFET 100A in accordance with the first variant includes a first electrically conductive stress-having film 7c in place of both the silicide layer 7b and the first stress-having film 11, comparing to the n-channel type MOSFET 100 in accordance with the first exemplary embodiment, illustrated in FIG. 1.

The n-channel type MOSFET 100A in accordance with the first variant is structurally identical with the n-channel type MOSFET 100 in accordance with the first exemplary embodiment except including the first electrically conductive stress-having film 7c in place of both the silicide layer 7b and the first stress-having film 11. Accordingly, parts or elements that correspond to those of the n-channel type MOSFET 100 in accordance with the first exemplary embodiment have been provided with the same reference numerals, and are not explained hereinbelow.

The first electrically conductive stress-having film 7c is formed at least partially on the gate electrode 7 of the n-channel type MOSFET 100A, and is comprised of a layer which has a high electrical conductivity and to which compressive stress is imparted.

For instance, the first electrically conductive stress-having film 7c is composed of silicide containing one of cobalt, nickel and titanium, tungsten, aluminum, copper, or platinum.

For instance, the first electrically conductive stress-having film 7c may be formed by sputtering or a combination of chemical vapor deposition and annealing.

A method of fabricating the n-channel type MOSFET 100A in accordance with the first variant is identical with a method of fabricating the n-channel type MOSFET 100 in accordance with the first exemplary embodiment except conditions for forming films and carrying out dry etching.

The n-channel type MOSFET 100A in accordance with the first variant provides the same advantages as those provided by the n-channel type MOSFET 100 in accordance with the first exemplary embodiment. That is, it is possible to distort a channel in a direction in which tensile stress is applied, and to significantly enhance mobility of electrons in a channel region of the n-channel type MOSFET.

Similarly to the n-channel type MOSFET 100 in accordance with the first exemplary embodiment, it is preferable in the n-channel type MOSFET 100A in accordance with the first variant that a semiconductor substrate is composed of silicon or silicon containing therein germanium or carbon. This is applied to all exemplary embodiments and variants thereof described hereinbelow.

The present variant can be applied not only to the first exemplary embodiment, but also to all exemplary embodiments and variants thereof described hereinbelow.

### Second Exemplary Embodiment

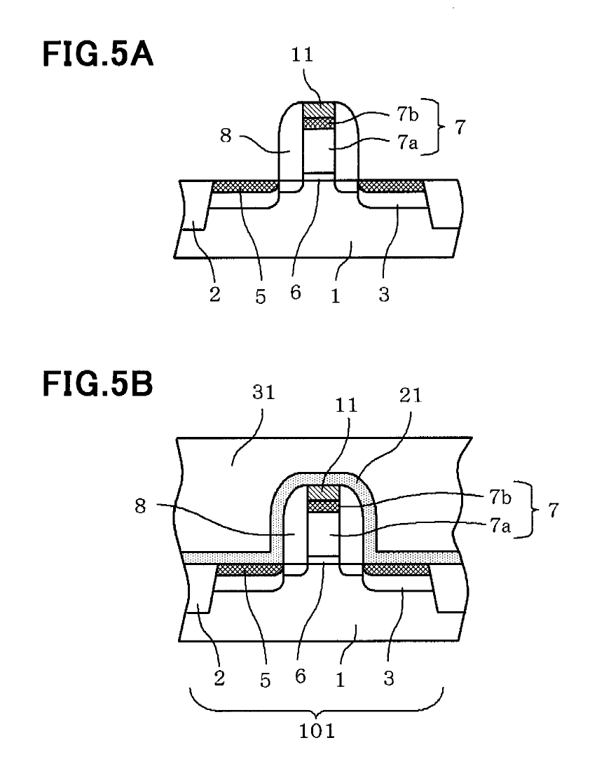

FIG. 5B is a cross-sectional view of an n-channel type MOSFET 101 in accordance with the second exemplary embodiment of the present invention.

In comparison with the n-channel type MOSFET 100 in accordance with the first exemplary embodiment, the n-channel type MOSFET 101 in accordance with the second exemplary embodiment additionally includes a third stress-having film 21 covering the gate electrode 7, the sidewall spacer 8, and the source/drain regions therewith, and having tensile stress.

The n-channel type MOSFET 101 in accordance with the second exemplary embodiment is structurally identical with the n-channel type MOSFET 100 in accordance with the first exemplary embodiment except additionally including the third stress-having film 21 having tensile stress therein. Accordingly, parts or elements that correspond to those of the n-channel type MOSFET 100 in accordance with the first exemplary embodiment have been provided with the same reference numerals, and are not explained hereinbelow.

Hereinbelow is explained the advantages provided by the n-channel type MOSFET 101 in accordance with the second exemplary embodiment.

The first stress-having film 11 formed on the gate electrode 7 and having compressive stress therein imparts tensile stress to a channel, similarly to the n-channel type MOSFET 100 in accordance with the first exemplary embodiment. In addition, the third stress-having film 21 having tensile stress therein further imparts tensile stress to a channel. Thus, a channel is distorted in a direction in which the tensile stresses are imparted, resulting in significant enhancement in mobility of electrons in a channel region of the n-channel type MOSFET.

FIGS. 5A and 5B are cross-sectional views showing steps to be carried out in a method of fabricating the n-channel type MOSFET 101 in accordance with the second exemplary embodiment.

Hereinbelow is explained a method of fabricating the n-channel type MOSFET 101 in accordance with the second exemplary embodiment, with reference to FIGS. 5A and 5B.

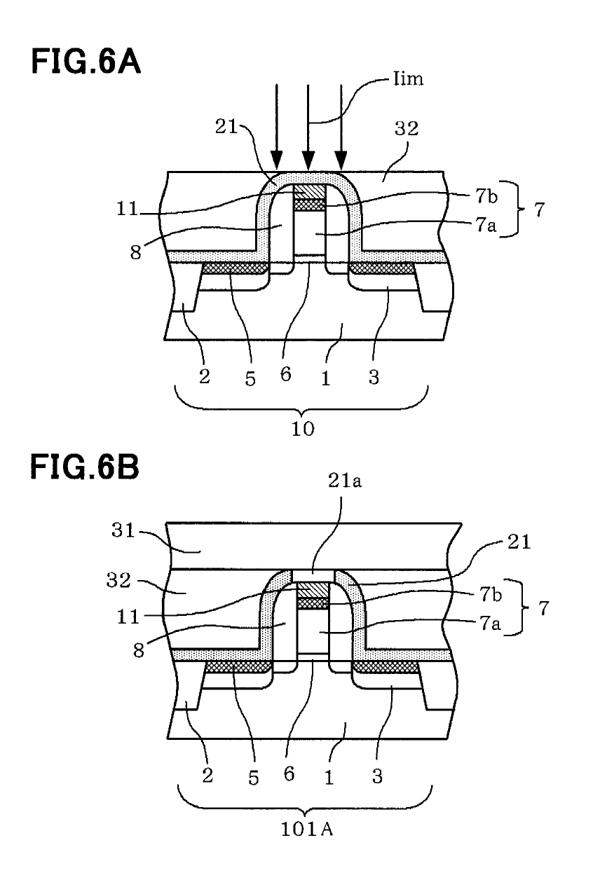

First, there is obtained a structure illustrated in FIG. 6A by carrying out steps identical to the steps illustrated in FIGS. 3A to 3C in a method of fabricating the n-channel type MOSFET 100 in accordance with the first exemplary embodiment.

Then, as illustrated in FIG. 5B, there is formed the third stress-having film 21 having tensile stress so as to cover the gate electrode, the sidewall spacer, and the source/drain regions therewith.

The third stress-having film 21 is comprised of an electrically insulating film having tensile stress therein, and is comprised of, for instance, a silicon nitride film formed by thermochemical vapor deposition or atomic layer deposition.

Finally, the interlayer insulating film 31 is formed. Thus, there is obtained the n-channel type MOSFET 101 in accordance with the second exemplary embodiment, as illustrated in FIG. 5B.

Thereafter, a contact hole is formed, and then, a contact plug is formed in the contact hole. Then, necessary wires are arranged on the contact plug.

### First Variant of Second Exemplary Embodiment

FIG. 6B is a cross-sectional view of an n-channel type MOSFET 101A in accordance with a first variant of the second exemplary embodiment.

The n-channel type MOSFET 101A in accordance with the first variant is structurally different from the n-channel type MOSFET 101 in accordance with the second exemplary embodiment, illustrated in FIG. 5B, in that the third stress-having film 21 is designed to include a stress-relaxing portion 21a disposed on the first stress-having film 11. Specifically, the third stress-having film 21 is designed to be partially cut out above the first stress-having film 11, and hence, the third stress-having film 21 has no stress in the stress-relaxing portion 21a, that is, above the first stress-having film 11.

The n-channel type MOSFET 101A in accordance with the present variant is structurally identical with the n-channel type MOSFET 101 in accordance with the second exemplary embodiment except including the stress-relaxing portion 21a. Accordingly, parts or elements that correspond to those of the n-channel type MOSFET 101 in accordance with the second exemplary embodiment have been provided with the same reference numerals, and are not explained hereinbelow.

In the n-channel type MOSFET 101 in accordance with the second exemplary embodiment, the third stress-having film 21 having tensile stress, formed on the first stress-having film 11 having compressive stress imparts compressive distortion to a channel. In the n-channel type MOSFET 101A in accordance with the present variant, since the portion of the third stress-having film 21 disposed on the first stress-having film 11 has no stress, compressive distortion is not imparted to a channel. Accordingly, the n-channel type MOSFET 101A in accordance with the present variant can distort a channel to a higher degree than the n-channel type MOSFET 101 in accordance with the second exemplary embodiment, and hence, can further enhance mobility of electrons in a channel region of an n-channel type MOSFET.

FIGS. 6A and 6B are cross-sectional views showing steps to be carried out in a method of fabricating the n-channel type MOSFET 101A in accordance with the present variant.

Hereinbelow is explained a method of fabricating the n-channel type MOSFET 101A in accordance with the present variant, with reference to FIGS. 6A and 6B.

By carrying out a method of fabricating the n-channel type MOSFET 101 in accordance with the second exemplary embodiment, a transistor is fabricated until it includes the third stress-having film 21 having tensile stress. Then, there is formed an interlayer oxide film 32 having a thickness equal to or greater than a height of the gate electrode.

For instance, the interlayer oxide film 32 is comprised of a silicon oxide film.

Then, the interlayer oxide film 32 is removed by chemical mechanical polishing (CMP) until the first stress-having film 11 appears. A structure at this stage is illustrated in FIG. 6A.

Then, ions Iim such as silicon, germanium, argon or xenon are implanted into the third stress-having film 21.

Herein, ion implantation energy is selected such that a depth to which ions reach is almost equal to a thickness of the third stress-having film 21, and a volume of ions is selected such that stress of the third stress-having film 21 is sufficiently relaxed.

Then, the interlayer insulating film 31 is formed. Thus, there is obtained the n-channel type MOSFET 101A in accordance with the present variant, illustrated in FIG. 6B.

Thereafter, a contact hole is formed, and then, a contact plug is formed in the contact hole. Then, necessary wires are arranged on the contact plug.

### Second Variant of Second Exemplary Embodiment

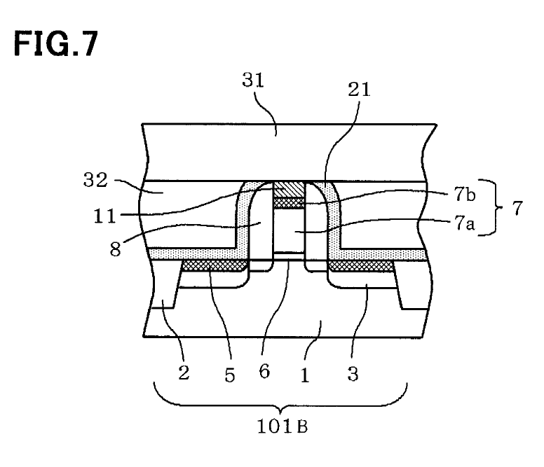

FIG. 7 is a cross-sectional view of an n-channel type MOSFET 101B in accordance with a second variant of the second exemplary embodiment.

In the n-channel type MOSFET 101B in accordance with the present variant, similarly to the n-channel type MOSFET 101A in accordance with the first variant illustrated in FIG. 6, the interlayer insulating film 32 is removed by chemical mechanical polishing until a surface of the first stress-having film 11 appears, after the third stress-having film 21 and the interlayer insulating film 32 are formed.

Since the third stress-having film 21 having tensile stress therein is not formed at a surface of the first stress-having film 11, the n-channel type MOSFET 101B in accordance with the present variant can provide the same advantages as those provided by the n-channel type MOSFET 101A in accordance with the first variant.

Furthermore, comparing to the n-channel type MOSFET 101A in accordance with the first variant, it is possible to omit a step of implanting ions.

### Third Variant of Second Exemplary Embodiment

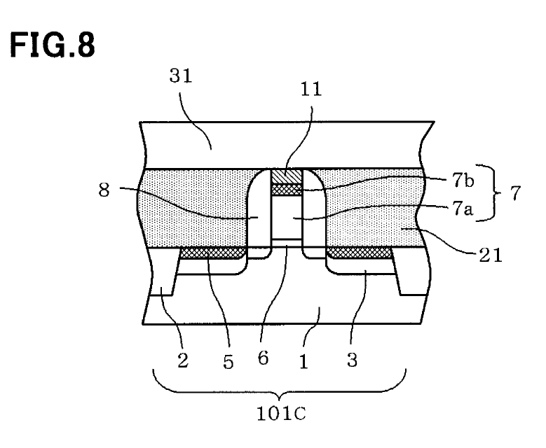

FIG. 8 is a cross-sectional view of an n-channel type MOSFET 101C in accordance with a third variant of the second exemplary embodiment.

In the n-channel type MOSFET 101C in accordance with the present variant, the first stress-having film 21 is formed to have such a thickness that the first stress-having film 21 is higher than the gate electrode 7, and then, the first stress-having film 21 is removed by chemical mechanical polishing until a surface of the first stress-having film 11 appears without forming the interlayer oxide film 32.

The n-channel type MOSFET 101C in accordance with the present variant can provide the same advantages as those provided by the n-channel type MOSFET 101B in accordance with the second variant.

Furthermore, comparing to the n-channel type MOSFET 101B in accordance with the second variant, it is possible to omit a step of forming the interlayer oxide film 32.

### Fourth Variant of Second Exemplary Embodiment

The n-channel type MOSFET 101C in accordance with the third variant of the second exemplary embodiment, illustrated in FIG. 8, may be applied to a p-channel type MOSFET.

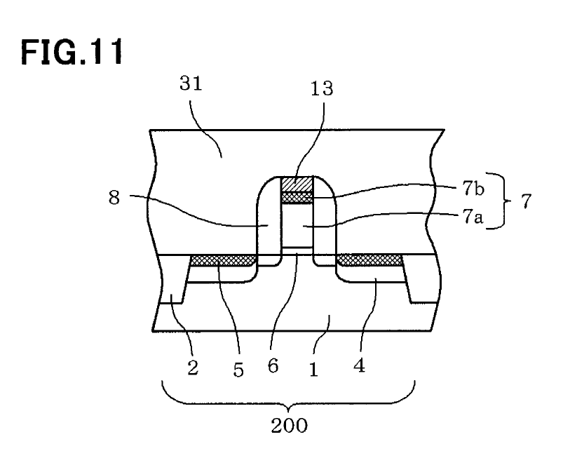

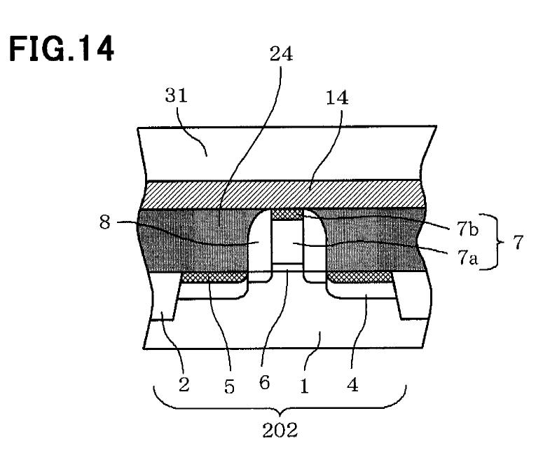

A p-channel type MOSFET in accordance with a fourth variant of the second exemplary embodiment is designed to include a second stress-having film 13 having tensile stress therein (see later-mentioned FIG. 11), in place of the first stress-having film 11, and further include a seventh stress-having film 24 having compressive stress therein (see later-mentioned FIG. 14), in place of the third stress-having film 21.

### Fifth Variant of Second Exemplary Embodiment

Furthermore, it is possible to fabricate a CMOSFET by combining the n-channel type MOSFET 101C in accordance with the third variant of the second exemplary embodiment and the p-channel type MOSFET in accordance with the fourth variant of the second exemplary embodiment with each other.

### Third Exemplary Embodiment

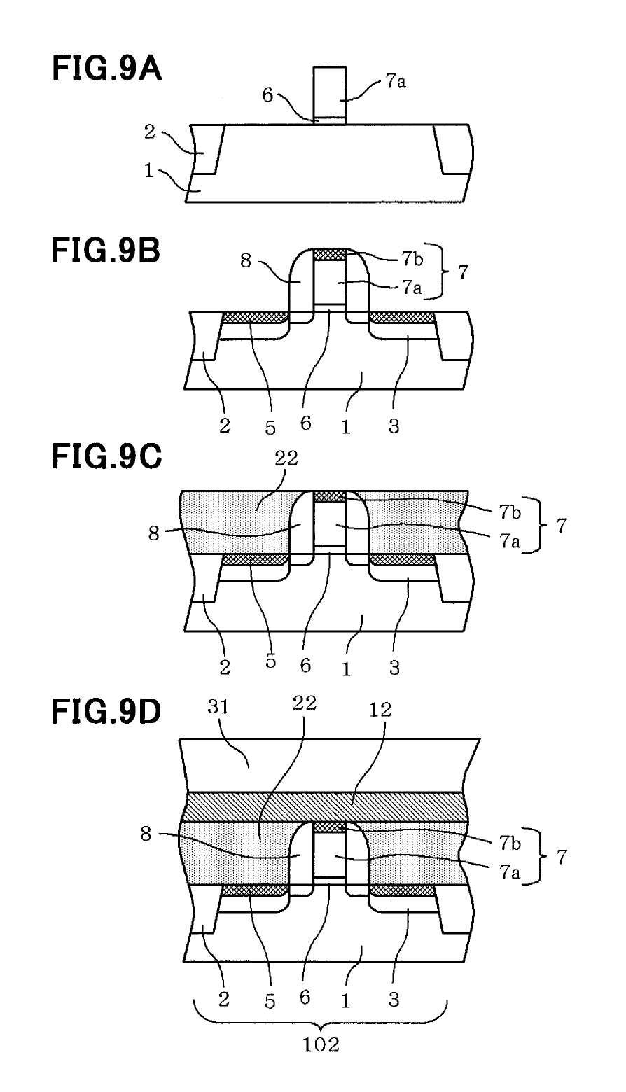

FIG. 9D is a cross-sectional view of an n-channel type MOSFET 102 in accordance with the third exemplary embodiment of the present invention.

The n-channel type MOSFET 102 in accordance with the present exemplary embodiment is comprised of a silicon substrate 1, device separation regions 2 formed at a surface of the silicon substrate 1, a gate insulating film 6 formed on a surface of the silicon substrate 1 in a region sandwiched between the device separation regions 2, a gate electrode 7 having a two-layered structure including a silicon film 7a and a silicide layer 7b both formed on the gate insulating film 6, n-type impurity diffusing layers 3 formed at a surface of the silicon substrate 1 and making source/drain regions, silicide layers 5 formed on the n-type impurity diffusing layers 3, a sidewall spacer 8 covering sidewalls of the gate insulating film 6 and the gate electrode 7 therewith, a fifth stress-having film 22 having the same height at that of the gate electrode 7, covering source/drain regions of the n-channel type MOSFET 102 therewith, and having tensile stress, a sixth stress-having film 12 formed on both the gate electrode 7 and the fifth stress-having film 22, and having compressive film 12, and an interlayer insulating film 31 being formed entirely on the sixth stress-having film 12.

In the n-channel type MOSFET 102 in accordance with the present exemplary embodiment, the fifth stress-having film 22 having tensile stress therein is designed to have almost the same height as that of the gate electrode 7, and the sixth stress-having film 12 having compressive stress is formed on the fifth stress-having film 22. Thus, in the n-channel type MOSFET 102 in accordance with the present exemplary embodiment, since the sixth stress-having film 22 having tensile stress is formed thick both around the gate electrode 7 and on the source/drain regions, high tensile distortion is applied to a channel, resulting in significant enhancement in mobility of electrons in a channel region of an n-channel type MOSFET.

FIGS. 9A to 9D are cross-sectional views showing steps to be carried out in a method of fabricating the n-channel type MOSFET 102 in accordance with the present exemplary embodiment.

Hereinbelow is explained a method of fabricating the n-channel type MOSFET 102 in accordance with the present exemplary embodiment, with reference to FIGS. 9A to 9D.

As illustrated in FIG. 9A, similarly to a method of fabricating a related MOSFET, the device separation regions 2 are formed at a surface of the silicon substrate 1. Then, the gate insulating film 6 is formed on the substrate in a region surrounded by the device separation regions 2. Then, the silicon film 7a patterned into a gate electrode is formed on the gate insulating film 6.

The above-mentioned step is different from the step in the first exemplary embodiment, illustrated in FIG. 3B, in that the silicide layer 7b and the first stress-having film 11 are not formed on the silicon film 7a.

Then, ions are implanted into the silicon substrate 1 to form the silicide layer 5 acting as shallow source/drain regions. There is formed the sidewall spacer 8. Ions are implanted into the silicon substrate 1 to form the n-type impurity layer 3 acting as deep source/drain regions. Then, the silicon substrate 1 is annealed for activating the impurities to thereby complete the silicide layers 5 and 7b. The structure at this stage is illustrated in FIG. 9B.

For instance, the silicide layers 5 and 7b may be comprised of a silicide film containing therein metal such as cobalt or nickel.

Then, the fifth stress-having film 22 having tensile stress therein is formed to have a thickness greater than a thickness of the gate electrode 7. Then, the fifth stress-having film 22 is removed by chemical mechanical polishing until an upper surface of the gate electrode 7 appears. The structure at this stage is illustrated in FIG. 9C.

The fifth stress-having film 22 is comprised of an electrically insulating film having tensile stress therein. For instance, the fifth stress-having film 22 is comprised of a silicon nitride film formed by thermochemical vapor deposition or atomic layer deposition.

Then, the sixth stress-having film 12 having compressive stress is formed on both the fifth stress-having film 22 and the gate electrode 7. Then, the interlayer insulating film 31 is formed on the sixth stress-having film 12. Thus, there is obtained the structure illustrated in FIG. 9D.

The sixth stress-having film 12 is comprised of an electrically insulating film having compressive stress therein. For instance, the sixth stress-having film 12 is comprised of a silicon nitride film formed by plasma-enhanced chemical vapor deposition.

The sixth stress-having film 12 may be composed of materials mentioned above as materials of which the first stress-having film 11 is composed in the first exemplary embodiment.

Thereafter, a contact hole is formed, and then, a contact plug is formed in the contact hole. Then, necessary wires are arranged on the contact plug.

### First Variant of Third Exemplary Embodiment

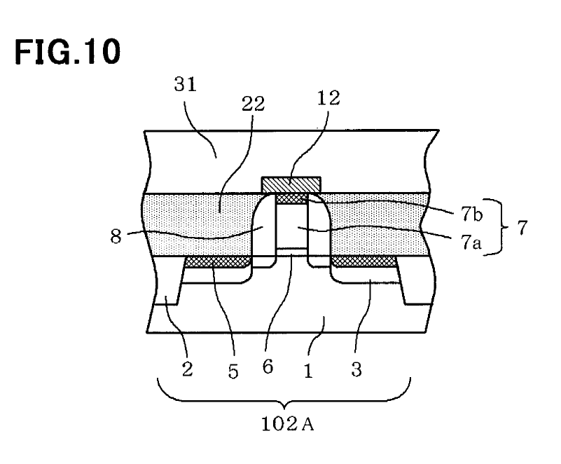

FIG. 10 is a cross-sectional view of an n-channel type MOSFET 102A in accordance with a first variant of the third exemplary embodiment.

The n-channel type MOSFET 102A in accordance with the first variant is structurally different from the n-channel type MOSFET 102 in accordance with the third exemplary embodiment in a shape of the sixth stress-having film 12. Specifically, whereas the sixth stress-having film 12 is formed to entirely cover both the gate electrode 7 and the fifth stress-having film 22 therewith in the n-channel type MOSFET 102 in accordance with the third exemplary embodiment, the sixth stress-having film 12 is formed only on the gate electrode 7 in the n-channel type MOSFET 102A in accordance with the present variant.

The sixth stress-having film 12 in the present variant is, after the sixth stress-having film 12 is formed entirely on both the gate electrode 7 and the fifth stress-having film 22, patterned by photolithography so that the sixth stress-having film 12 remains only on the gate electrode 7.

In the n-channel type MOSFET 102A in accordance with the present variant, since the sixth stress-having film 12 having compressive stress therein is not substantially formed on the fifth stress-having film 22 having tensile stress therein, stress caused by the fifth stress-having film 22 is not weakened by the sixth stress-having film 12, resulting in that it is possible to impart high tensile distortion to a channel.

### Second Variant of Third Exemplary Embodiment

The structure of the n-channel type MOSFET 102A in accordance with the first variant of the third exemplary embodiment, illustrated in FIG. 10, can be applied to a p-channel type MOSFET.

A p-channel type MOSFET in accordance with a second variant of the third exemplary embodiment is designed to include a stress-having film having tensile stress therein, in place of the sixth stress-having film 12 having compressive stress therein, and further include a stress-having film having compressive stress therein, in place of the fifth stress-having film 22 having tensile stress therein.

### Fourth Exemplary Embodiment

FIG. 11 is a cross-sectional view of a p-channel type field effect transistor (MOSFET) 200 in accordance with the fourth exemplary embodiment of the present invention.

The p-channel type MOSFET 200 in accordance with the fourth exemplary embodiment is comprised of a silicon substrate 1, device separation regions 2 formed at a surface of the silicon substrate 1, a gate insulating film 6 formed on a surface of the silicon substrate 1 in a region sandwiched between the device separation regions 2, a gate electrode 7 having a two-layered structure including a silicon film 7a and a silicide layer 7b both formed on the gate insulating film 6, p-type impurity diffusing layers 4 formed at a surface of the silicon substrate 1 and making source/drain regions, silicide layers 5 formed on the p-type impurity diffusing layers 4, a second stress-having film 13 being formed on the gate electrode 7 and having tensile stress, a sidewall spacer 8 covering sidewalls of the gate insulating film 6, the gate electrode 7 and the second stress-having film 13 therewith, and an interlayer insulating film 31 being formed entirely on the silicon substrate 1.

Hereinbelow are explained the advantages provided by the p-channel type MOSFET 200 in accordance with the fourth exemplary embodiment.

The p-channel type MOSFET 200 in accordance with the fourth exemplary embodiment is structurally different from the n-channel type MOSFET 100 in accordance with the first exemplary embodiment only in that a direction of the stress in the first stress-having film 11 is just opposite to a direction of the stress in the second stress-having film 13. Accordingly, a degree of the advantages provided by the p-channel type MOSFET 200 in accordance with the fourth exemplary embodiment is equal to that of the n-channel type MOSFET 100 in accordance with the first exemplary embodiment. Since the second stress-having film 13 having tensile stress therein imparts compressive distortion to a channel, it is possible to enhance mobility of holes in a channel region of a pMOSFET.

Hereinbelow is explained a method of fabricating the p-channel type MOSFET 200 in accordance with the fourth exemplary embodiment.

Since the p-channel type MOSFET 200 in accordance with the fourth exemplary embodiment is structurally different from the n-channel type MOSFET 100 in accordance with the first exemplary embodiment only in a polarity of a MOSFET, a method of fabricating the p-channel type MOSFET 200 in accordance with the fourth exemplary embodiment is fundamentally identical with a method of fabricating the n-channel type MOSFET 100 in accordance with the first exemplary embodiment. They are different from each other only in selecting semiconductor materials to ensure a difference in a polarity of a MOSFET.

The second stress-having film 13 is comprised of an electrically insulating film having tensile stress therein. For instance, the second stress-having film 13 is comprised of a silicon nitride film formed by thermochemical vapor deposition or atomic layer deposition.

The second stress-having film 13 may be composed of materials mentioned above as materials of which the first stress-having film 11 is composed in the n-channel type MOSFET 100 in accordance with the first exemplary embodiment.

In the p-channel type MOSFET 200 in accordance with the present exemplary embodiment, similarly to the first variant of the n-channel type MOSFET 100 in accordance with the first exemplary embodiment, an electrically conductive film having tensile stress therein may be used in place of the second stress-having film 13 and the silicide layer 7b.

The electrically conductive stress-having film used herein (which corresponds to the electrically conductive stress-having film 7c illustrated in FIG. 4) may be composed of silicide containing one of cobalt, nickel and titanium, tungsten, aluminum, copper, or platinum.

The electrically conductive stress-having film is formed by sputtering or a combination of chemical vapor deposition and annealing.

A method of fabricating the p-channel type MOSFET including the electrically conductive stress-having film in place of both the second stress-having film 13 and the silicide layer 7b is identical with a method of fabricating the p-channel type MOSFET 200 in accordance with the present exemplary embodiment except conditions for forming a gate film and conditions for carrying out dry etching.

By using the electrically conductive stress-having film in place of both the second stress-having film 13 and the silicide layer 7b, it is possible to have the same advantages as those provided by the p-channel type MOSFET 200 in accordance with the present exemplary embodiment. Specifically, it is possible to distort a channel in a direction in which compressive stress is applied, and significantly enhance mobility of holes in a channel region of a pMOSFET.

The electrically conductive stress-having film may be used in place of both the second stress-having film 13 and the silicide layer 7b in p-channel type MOSFETs in accordance with later-mentioned exemplary embodiments and variants thereof.

### Fifth Exemplary Embodiment

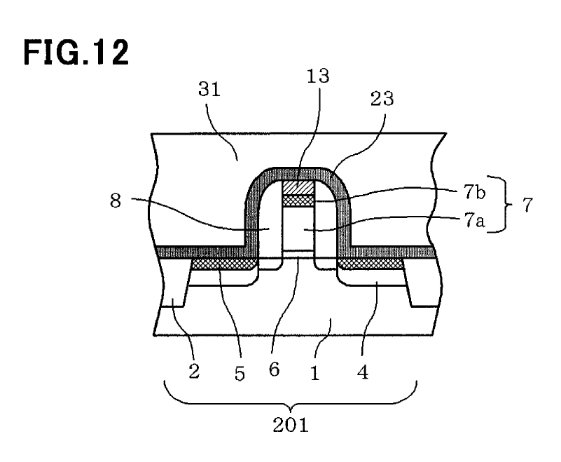

FIG. 12 is a cross-sectional view of a p-channel type MOSFET 201 in accordance with the fifth exemplary embodiment of the present invention.

The p-channel type MOSFET 201 in accordance with the fifth exemplary embodiment is structurally different from the p-channel type MOSFET 200 in accordance with the fourth exemplary embodiment, illustrated in FIG. 11, in additionally including a fourth stress-having film 23 covering the gate electrode 7, the sidewall spacer 8, and the source/drain regions therewith, and having compressive stress.

The p-channel type MOSFET 201 in accordance with the present exemplary embodiment is structurally identical with the p-channel type MOSFET 200 in accordance with the fourth exemplary embodiment except additionally including the fourth stress-having film 23 having compressive stress. Accordingly, parts or elements that correspond to those of the p-channel type MOSFET 200 in accordance with the fourth exemplary embodiment have been provided with the same reference numerals, and are not explained hereinbelow.

Hereinbelow are explained the advantages provided by the p-channel type MOSFET 201 in accordance with the present exemplary embodiment.

Similarly to the p-channel type MOSFET 200 in accordance with the fourth exemplary embodiment, since the second stress-having film 13 formed on the gate electrode 7 and having tensile stress therein imparts compressive stress to a channel, and further, the fourth stress-having film 23 formed covering the gate electrode 7, the sidewall spacer 8, and the source/drain regions therewith, and having compressive stress therein imparts compressive stress to a channel, the channel is distorted in a direction in which the stresses are applied, resulting in significant enhancement in mobility of holes in a channel region in a pMOSFET.

Since the p-channel type MOSFET 201 in accordance with the present exemplary embodiment is structurally different from the n-channel type MOSFET 101 in accordance with the second exemplary embodiment only in a polarity of a MOSFET, a method of fabricating the p-channel type MOSFET 201 in accordance with the present exemplary embodiment is fundamentally identical with a method of fabricating the n-channel type MOSFET 101 in accordance with the second exemplary embodiment. They are different from each other only in selecting semiconductor materials to ensure a difference in a polarity of a MOSFET.

The fourth stress-having film 23 is comprised of an electrically insulating film having compressive stress. For instance, the fourth stress-having film 23 is comprised of a silicon nitride film formed by plasma-enhanced chemical vapor deposition.

### First Variant of Fifth Exemplary Embodiment

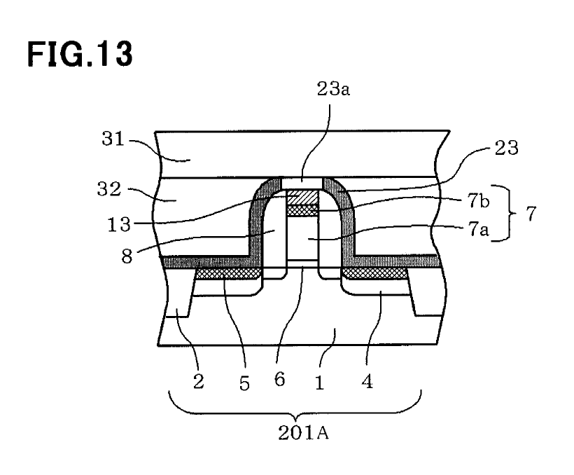

FIG. 13 is a cross-sectional view of a p-channel type MOSFET 201A in accordance with a first variant of the fifth exemplary embodiment.

The p-channel type MOSFET 201A in accordance with the present variant is structurally different from the p-channel type MOSFET 201 in accordance with the fifth exemplary embodiment, illustrated in FIG. 12, in that the fourth stress-having film 23 is designed to include a stress-relaxing portion 23a disposed on the second stress-having film 13. Specifically, the fourth stress-having film 23 is designed to be partially cut out above the second stress-having film 13, and hence, the fourth stress-having film 23 has no stress in the stress-relaxing portion 23a, that is, above the second stress-having film 13.

The p-channel type MOSFET 201A in accordance with the present variant is structurally identical with the p-channel type MOSFET 201 in accordance with the fifth exemplary embodiment except including the stress-relaxing portion 23a. Accordingly, parts or elements that correspond to those of the p-channel type MOSFET 201 in accordance with the fifth exemplary embodiment have been provided with the same reference numerals, and are not explained hereinbelow.

In the p-channel type MOSFET 201 in accordance with the fifth exemplary embodiment, the fourth stress-having film 23 having compressive stress, formed on the second stress-having film 13 having tensile stress imparts tensile distortion to a channel. In the p-channel type MOSFET 201A in accordance with the present variant, since the portion of the fourth stress-having film 23 disposed on the second stress-having film 13 has no stress, tensile distortion is not imparted to a channel. Accordingly, the p-channel type MOSFET 201A in accordance with the present variant can distort a channel to a higher degree than the p-channel type MOSFET 201 in accordance with the fifth exemplary embodiment, and hence, can further enhance mobility of holes in a channel region of a p-channel type MOSFET.

Since the p-channel type MOSFET 201A in accordance with the present variant is structurally different from the p-channel type MOSFET 101A in accordance with the first variant of the second exemplary embodiment only in a polarity of a MOSFET, a method of fabricating the p-channel type MOSFET 201A in accordance with the present variant is fundamentally identical with a method of fabricating the p-channel type MOSFET 101A in accordance with the first variant of the second exemplary embodiment. They are different from each other only in selecting semiconductor materials to ensure a difference in a polarity of a MOSFET.

As variants of the p-channel type MOSFET 201 in accordance with the fifth exemplary embodiment, the second and third variants of the n-channel type MOSFET 101 in accordance with the second exemplary embodiment may be selected.

Specifically, similarly to the n-channel type MOSFET 101B (FIG. 7) in accordance with the second variant of the second exemplary embodiment, a portion of the fourth stress-having film 23 higher than the second stress-having film 13 can be removed by chemical mechanical polishing.

Similarly to the n-channel type MOSFET 101C (FIG. 8) in accordance with the third variant of the second exemplary embodiment, after forming the fourth stress-having film 23 to have a thickness higher than a surface of the second stress-having film 13, the fourth stress-having film 23 may be polished until a surface of the second stress-having film 13 appears.

### Sixth Exemplary Embodiment

FIG. 14 is a cross-sectional view of a p-channel type MOSFET 202 in accordance with the sixth exemplary embodiment.

The p-channel type MOSFET 202 in accordance with the present exemplary embodiment is comprised of a silicon substrate 1, device separation regions 2 formed at a surface of the silicon substrate 1, a gate insulating film 6 formed on a surface of the silicon substrate 1 in a region sandwiched between the device separation regions 2, a gate electrode 7 having a two-layered structure including a silicon film 7a and a silicide layer 7b both formed on the gate insulating film 6, p-type impurity diffusing layers 4 formed at a surface of the silicon substrate 1 and making source/drain regions, silicide layers 5 formed on the p-type impurity diffusing layers 4, a sidewall spacer 8 covering sidewalls of the gate insulating film 6 and the gate electrode 7 therewith, a seventh stress-having film 24 having the same height at that of the gate electrode 7, covering source/drain regions of the p-channel type MOSFET 202 therewith, and having compressive stress, an eighth stress-having film 14 formed on both the gate electrode 7 and the seventh stress-having film 24, and having tensile film 12, and an interlayer insulating film 31 being formed entirely on the eighth stress-having film 14.

In the p-channel type MOSFET 202 in accordance with the present exemplary embodiment, the seventh stress-having film 24 having compressive stress therein is designed to have almost the same height as that of the gate electrode 7, and the eighth stress-having film 14 having tensile stress is formed on the seventh stress-having film 24. Thus, in the p-channel type MOSFET 202 in accordance with the present exemplary embodiment, since the seventh stress-having film 24 having compressive stress therein is formed thick both around the gate electrode 7 and on the source/drain regions, high tensile distortion is applied to a channel, resulting in significant enhancement in mobility of holes in a channel region of a p-channel type MOSFET.

Since the p-channel type MOSFET 202 in accordance with the present exemplary embodiment is structurally different from the n-channel type MOSFET 102 in accordance with the third exemplary embodiment only in a polarity of a MOSFET, a method of fabricating the p-channel type MOSFET 202 in accordance with the present exemplary embodiment is fundamentally identical with a method of fabricating the n-channel type MOSFET 102 in accordance with the third exemplary embodiment. They are different from each other only in selecting semiconductor materials to ensure a difference in a polarity of a MOSFET.

The seventh stress-having film 24 is comprised of an electrically insulating film having compressive stress therein. For instance, the seventh stress-having film 24 is comprised of a silicon nitride film formed by plasma-enhanced chemical vapor deposition.

The eighth stress-having film 14 is comprised of an electrically insulating film having tensile stress therein. For instance, the eighth stress-having film 14 is comprised of a silicon nitride film formed by thermochemical vapor deposition or atomic layer deposition.

The seventh stress-having film 24 and the eighth stress-having film 14 may be composed of materials mentioned above as materials of which the first stress-having film 11 is composed in the n-channel type MOSFET 100 in accordance with the first exemplary embodiment.

Similarly to the n-channel type MOSFET 102A in accordance with the first variant of the third exemplary embodiment, illustrated in FIG. 10, the eighth stress-having film 14 may be formed only on the gate electrode 7.

When the eighth stress-having film 14 is formed only on the gate electrode 7, the eighth stress-having film 14 is formed entirely on both the gate electrode 7 and the seventh stress-having film 24, and then, the eighth stress-having film 14 is patterned by photolithography so as to remain only on the gate electrode 7.

In the present variant, since the eighth stress-having film 14 having tensile stress therein is not substantially formed on the seventh stress-having film 24 having compressive stress therein, stress caused by the seventh stress-having film 24 is not weakened by the eighth stress-having film 14, resulting in that it is possible to impart high tensile distortion to a channel.

### Seventh Exemplary Embodiment

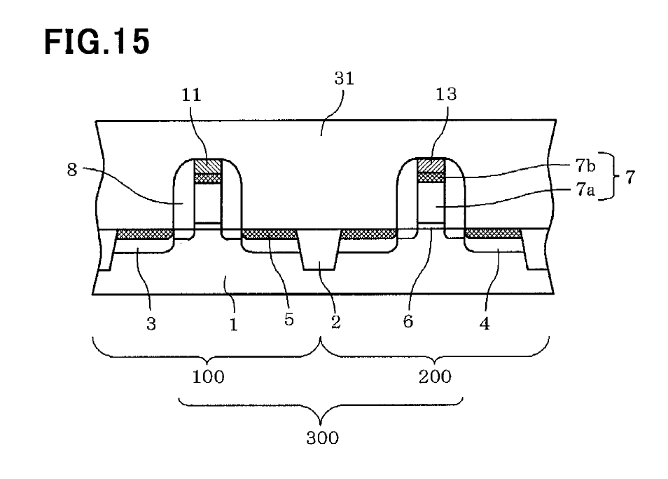

FIG. 15 is a cross-sectional view of a CMOSFET 300 in accordance with the seventh exemplary embodiment.

The CMOSFET 300 in accordance with the present exemplary embodiment is designed to include the n-channel type MOSFET 100 in accordance with the first exemplary embodiment, illustrated in FIG. 1, and the p-channel type MOSFET 200 in accordance with the fourth exemplary embodiment, illustrated in FIG. 11.

Specifically, the n-channel type MOSFET 100 as a part of the CMOSFET 300 in accordance with the present exemplary embodiment is comprised of a silicon substrate 1, device separation regions 2 formed at a surface of the silicon substrate 1, a gate insulating film 6 formed on a surface of the silicon substrate 1 in a region sandwiched between the device separation regions 2, a gate electrode 7 having a two-layered structure including a silicon film 7a and a silicide layer 7b both formed on the gate insulating film 6, n-type impurity diffusing layers 3 formed at a surface of the silicon substrate 1 and making source/drain regions, silicide layers 5 formed on the n-type impurity diffusing layers 3, a first stress-having film 11 being formed on the gate electrode 7 and having compressive stress, a sidewall spacer 8 covering sidewalls of the gate insulating film 6, the gate electrode 7 and the first stress-having film 11 therewith, and an interlayer insulating film 31 being formed entirely on the silicon substrate 1. The p-channel type MOSFET 200 as a part of the CMOSFET 300 in accordance with the present exemplary embodiment is comprised of a silicon substrate 1, device separation regions 2 formed at a surface of the silicon substrate 1, a gate insulating film 6 formed on a surface of the silicon substrate 1 in a region sandwiched between the device separation regions 2, a gate electrode 7 having a two-layered structure including a silicon film 7a and a silicide layer 7b both formed on the gate insulating film 6, p-type impurity diffusing layers 4 formed at a surface of the silicon substrate 1 and making source/drain regions, silicide layers 5 formed on the p-type impurity diffusing layers 4, a second stress-having film 13 being formed on the gate electrode 7 and having tensile stress, a sidewall spacer 8 covering sidewalls of the gate insulating film 6, the gate electrode 7 and the second stress-having film 13 therewith, and an interlayer insulating film 31 being formed entirely on the silicon substrate 1.

Hereinbelow are explained the advantage provided by the CMOSFET 300 in accordance with the present exemplary embodiment.

In the n-channel type MOSFET 100, similarly to the first exemplary embodiment, since the first stress-having film 11 formed on the gate electrode 7 and having compressive stress imparts tensile stress to a channel, the channel is distorted in a direction in which the tensile stress is applied, resulting in enhancement in mobility of electrons. In the p-channel type MOSFET 200, similarly to the fourth exemplary embodiment, since the second stress-having film 13 formed on the gate electrode 7 and having tensile stress imparts compressive stress to a channel, the channel is distorted in a direction in which the compressive stress is applied, resulting in enhancement in mobility of holes.

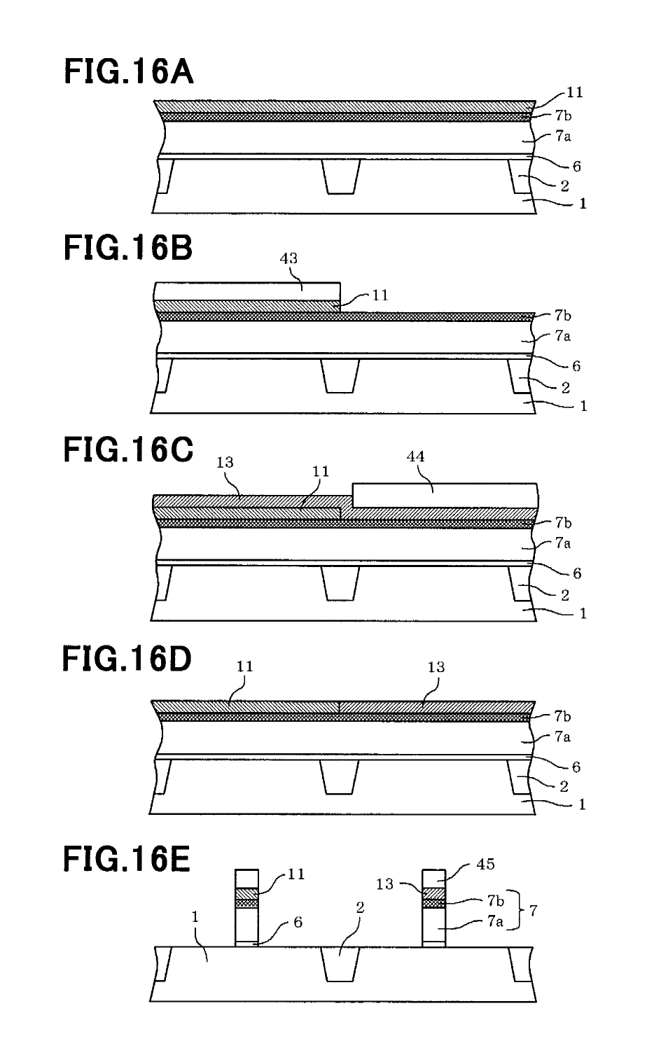

FIGS. 16A to 16E are cross-sectional views showing steps to be carried out in a method of fabricating the CMOSFET 300 in accordance with the present exemplary embodiment.

Hereinbelow is explained a method of fabricating the CMOSFET 300 in accordance with the present exemplary embodiment, with reference to FIGS. 16A to 16E.

First, similarly to a method of fabricating a related MOSFET, the device separation regions 2 are formed at a surface of the silicon substrate 1.

For instance, the device separation regions 2 may be comprised of a silicon oxide film, a silicon nitride film, or a film having a multi-layered structure including a silicon oxide film and a silicon nitride film.

Then, as illustrated in FIG. 16A, the gate insulating film 6, the silicon film 7a, the silicide layer 7b, and the first stress-having film 11 having compressive stress are formed on a surface of the silicon substrate 1 in this order.

For instance, the gate insulating film 6 may be comprised of a silicon oxide film, a film having a high dielectric constant and containing, for instance, nitrogen, hafnium, aluminum, titanium, zirconium or tantalum, or a film having a multi-layered structure including a silicon oxide film and the above-mentioned film having a high dielectric constant.

For instance, the silicon film 7a may be comprised of a polysilicon film, an amorphous silicon film, or a film having a multi-layered structure including a polysilicon film and an amorphous silicon film.

For instance, the silicide layer 7b contains therein metal such as cobalt or nickel.

The first stress-having film 11 is comprised of an electrically insulating film having compressive stress. For instance, the first stress-having film 11 is comprised of a silicon nitride film formed by plasma-enhanced chemical vapor deposition. The first stress-having film 11 may be composed of materials mentioned above as materials of which the first stress-having film 11 mentioned in the first exemplary embodiment is composed.

Then, a resist film 43 acting as an etching mask for etching the first stress-having film 11 is formed by known photolithography.

Then, a portion of the first stress-having film 11 existing in a region in which the p-channel type field effect transistor 200 is to be fabricated is removed by dry etching. The structure at this stage is illustrated in FIG. 16B.

Then, after removal of the resist film 43, the second stress-having film 13 having tensile stress is formed entirely on the silicon substrate 1.

The second stress-having film 13 is comprised of an electrically insulating film having tensile stress. For instance, the second stress-having film 13 is comprised of a silicon nitride film formed by thermochemical vapor deposition or atomic layer deposition.

The second stress-having film 13 may be composed of materials mentioned above as materials of which the first stress-having film 11 mentioned in the first exemplary embodiment is composed.

Then, as illustrated in FIG. 16C, a resist film 44 acting as an etching mask for etching the second stress-having film 13 is formed entirely on a region in which the p-channel type field effect transistor 209 is to be fabricated.

Then, a portion of the second stress-having film 13 existing in a region in which the n-channel type field effect transistor 100 is to be fabricated is removed by dry etching. Then, the resist film 44 is removed. The structure at this stage is illustrated in FIG. 16D.

Then, a resist film 45 acting as a mask for forming the gate electrode 7 is formed by photolithography. Then, the first stress-having film 11, the second stress-having film 13, the silicide layer 7b, the silicon film 7a and the gate insulating film 6 are removed by dry etching in portions not covered with the mask. The structure at this stage is illustrated in FIG. 16E.

After the resist film 45 was removed, there are carried out steps of implanting ions into the silicon substrate 1 to form shallow source/drain regions, forming the sidewall spacer 8, implanting ions into the silicon substrate 1 to form deep source/drain regions, annealing for activating the impurities, and forming the silicide layer 5.

For instance, the sidewall spacer 8 is comprised of a silicon oxide film, a silicon nitride film, or a film having a multi-layered structure including a silicon oxide film and a silicon nitride film.

For instance, the silicide layer 5 is comprised of a silicide film containing therein metal such as cobalt or nickel.

Then, the interlayer insulating film 31 is formed entirely on the silicon substrate 1. Thus, there is obtained the structure illustrated in FIG. 15.

Thereafter, a contact hole is formed, and then, a contact plug is formed in the contact hole. Then, necessary wires are arranged on the contact plug.

In the method of fabricating the CMOSFET 300, the first stress-having film 11 in the n-channel type field effect transistor 100 is first formed, and then, the second stress-having film 13 in the p-channel type field effect transistor 200 is formed. In contrast, the second stress-having film 13 may be first formed, and then, the first stress-having film 11 may be formed.

### First Variant of Seventh Exemplary Embodiment

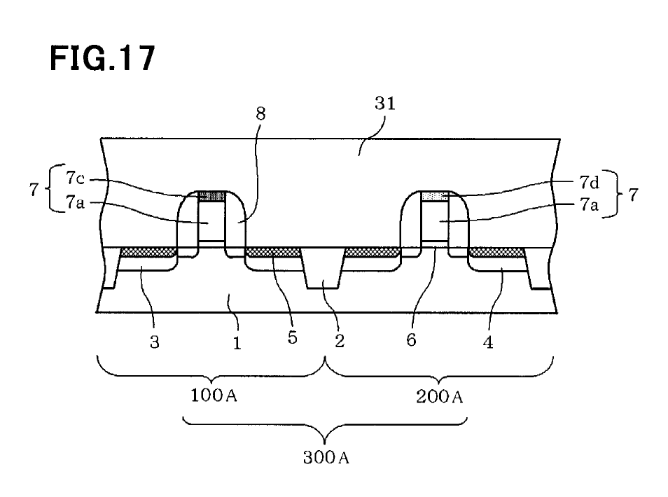

FIG. 17 is a cross-sectional view of a CMOSFET 300A in accordance with a first variant of the seventh exemplary embodiment.

The CMOSFET 300A in accordance with the present variant is comprised of the n-channel type MOSFET 100A in accordance with the first variant of the first exemplary embodiment, illustrated in FIG. 4, and a p-channel type MOSFET 200A.

The n-channel type MOSFET 100A is structurally different from the n-channel type MOSFET 100 in accordance with the first exemplary embodiment, illustrated in FIG. 1, in including a first electrically conductive stress-having film 7c having compressive stress, in place of the silicide layer 7b and the first stress-having film 11.

The p-channel type MOSFET 200A is structurally different from the p-channel type MOSFET 200 in accordance with the fourth exemplary embodiment, illustrated in FIG. 11, in including a second electrically conductive stress-having film 7d having tensile stress, in place of the silicide layer 7b and the second stress-having film 13.

The CMOSFET 300A in accordance with the present variant is structurally identical with the CMOSFET 300 in accordance with the seventh exemplary embodiment except including the first electrically conductive stress-having film 7c or the second electrically conductive stress-having film 7d in place of both the silicide layer 7b and the first stress-having film 11 or both the silicide layer 7b and the second stress-having film 13. Accordingly, parts or elements that correspond to those of the CMOSFET 300 in accordance with the seventh exemplary embodiment have been provided with the same reference numerals, and are not explained hereinbelow.

For instance, each of the electrically conductive stress-having films 7c and 7d is composed of silicide containing one of cobalt, nickel and titanium, tungsten, aluminum, copper, or platinum.

For instance, the electrically conductive stress-having films 7c and 7d may be formed by sputtering or a combination of chemical vapor deposition and annealing.

A method of fabricating the CMOSFET 300A in accordance with the present variant is identical with a method of fabricating the CMOSFET 300 in accordance with the seventh exemplary embodiment except in that the silicide layer 7b is not formed, and that the first electrically conductive stress-having film 7c and the second electrically conductive stress-having film 7d are used in place of the first stress-having film 11 and the second stress-having film 13.

The present variant provides the same advantages as those provided by the CMOSFET 300 in accordance with the seventh exemplary embodiment. Specifically, a channel is distorted in a direction in which tensile stress is applied in the n-channel MOSFET 100A, and a channel is distorted in a direction in which compressive stress is applied in the p-channel MOSFET 200A, resulting in enhancement in mobility of carriers in channel regions in both the n-channel MOSFET 100A and the p-channel MOSFET 200A.

### Eighth Exemplary Embodiment

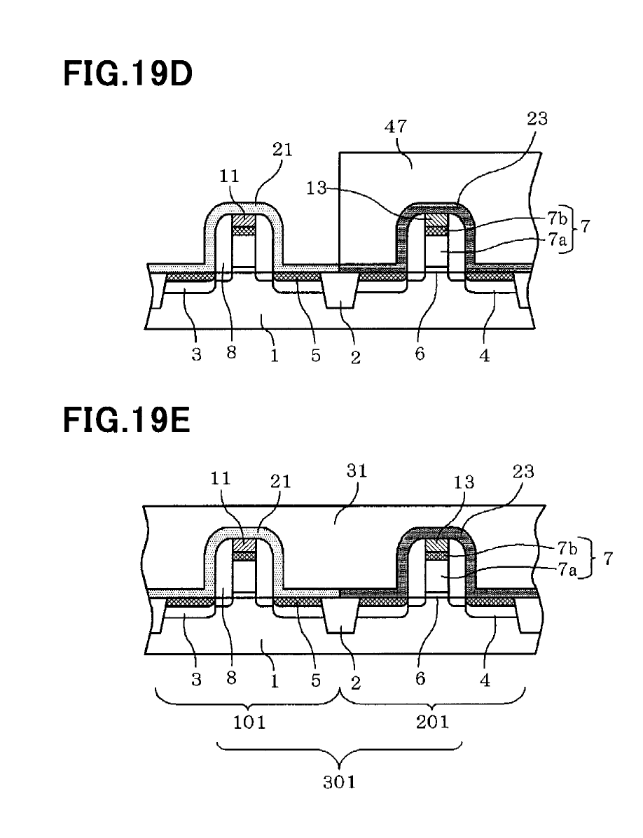

FIG. 19E is a cross-sectional view of a CMOSFET 301 in accordance with the eighth exemplary embodiment of the present invention.

The CMOSFET 301 in accordance with the present exemplary embodiment is comprised of the n-channel type MOSFET 101 in accordance with the second exemplary embodiment, illustrated in FIG. 5B, and the p-channel type MOSFET 201 in accordance with the fifth exemplary embodiment, illustrated in FIG. 12.

The CMOSFET 301 in accordance with the present exemplary embodiment is structurally different from the CMOSFET 300 (see FIG. 15) in accordance with the seventh exemplary embodiment in that a third stress-having film 21 having tensile stress is formed to cover the first stress-having film 11, the sidewall spacer 8, and the source/drain regions therewith in the n-channel type MOSFET 101, and a fourth stress-having film 23 having compressive stress is formed to cover the second stress-having film 13, the sidewall spacer 8, and the source/drain regions therewith in the p-channel type MOSFET 201.

The CMOSFET 301 in accordance with the present exemplary embodiment is structurally identical with the CMOSFET 300 in accordance with the seventh exemplary embodiment except the above-mentioned difference. Accordingly, parts or elements that correspond to those of the CMOSFET 300 in accordance with the seventh exemplary embodiment have been provided with the same reference numerals, and are not explained hereinbelow.

Hereinbelow are explained the advantage provided by the CMOSFET 301 in accordance with the present exemplary embodiment.

In the n-channel type MOSFET 101, similarly to the second exemplary embodiment, since the first stress-having film 11 formed on the gate electrode 7 and having compressive stress imparts tensile stress to a channel, and further, the third stress-having film 21 covering the first stress-having film 11, the sidewall spacer 8, and the source/drain regions therewith, and having tensile stress imparts tensile stress to a channel, the channel is distorted in a direction in which the tensile stress is applied, resulting in enhancement in mobility of electrons.

In the p-channel type MOSFET 201, similarly to the fifth exemplary embodiment, since the second stress-having film 13 formed on the gate electrode 7 and having tensile stress imparts compressive stress to a channel, and further, the fourth stress-having film 23 covering the second stress-having film 13, the sidewall spacer 8, and the source/drain regions therewith, and having compressive stress imparts compressive stress to a channel, the channel is distorted in a direction in which the compressive stress is applied, resulting in enhancement in mobility of holes.

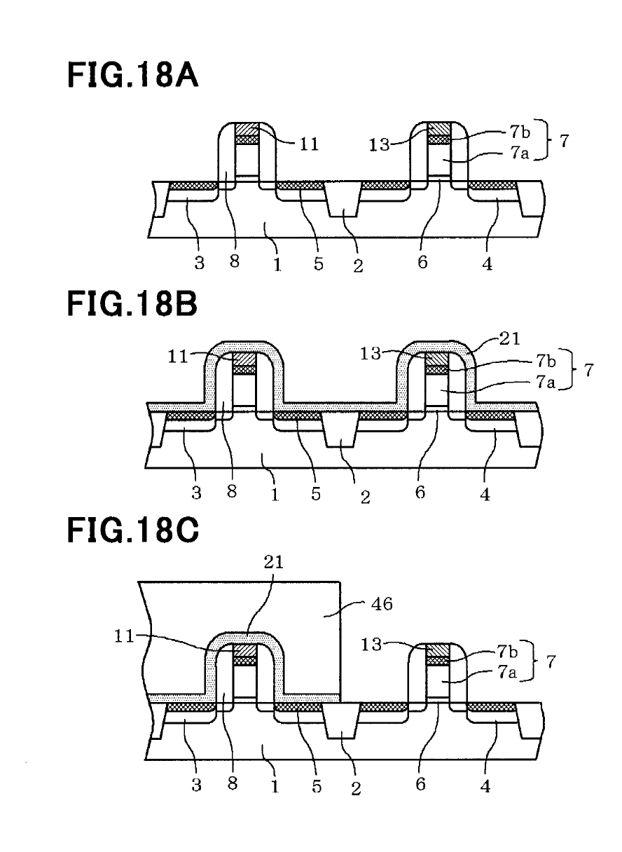

FIGS. 18A to 18C and FIGS. 19D to 19E are cross-sectional views showing steps to be carried out in a method of fabricating the CMOSFET 301 in accordance with the present exemplary embodiment.

Hereinbelow is explained a method of fabricating the CMOSFET 301 in accordance with the present exemplary embodiment, with reference to FIGS. 18A to 18C and FIGS. 19D to 19E.

By carrying out the steps identical with the steps included in a method of fabricating the CMOSFET 300 in accordance with the seventh exemplary embodiment, illustrated in FIGS. 16A to 16E, and further, by carrying out steps of removing a resist film, implanting ions into the silicon substrate 1 to form shallow source/drain regions, forming the sidewall spacer 8, implanting ions into the silicon substrate 1 to form deep source/drain regions, annealing for activating the impurities, and forming the silicide layer 5, there is obtained the structure illustrated in FIG. 18A. The structure illustrated in FIG. 18A is identical with the structure of the CMOSFET 300 in accordance with the seventh exemplary embodiment.

Then, as illustrated in FIG. 18B, the third stress-having film 21 having tensile stress is formed entirely on the silicon substrate 1.

The third stress-having film 21 is comprised of an electrically insulating film having tensile stress therein. For instance, the third stress-having film 21 is comprised of a silicon nitride film formed by thermochemical vapor deposition or atomic layer deposition.

Though not illustrated, for instance, a thin silicon oxide film (about 10 nanometers thick or thinner) may be formed below the third stress-having film 21 as a protection film for avoiding the transistor from being damaged in an etching step to be carried out later, if necessary.

Then, there is formed a resist film 46 by known photolithography as an etching mask for etching the third stress-having film 21. Then, the third stress-having film 21 together with the above-mentioned protection film (if necessary) is removed by dry etching in a region in which the p-channel type MOSFET 201 is to be fabricated. The structure at this stage is illustrated in FIG. 18C.

After removal of the resist film 46, the fourth stress-having film 23 having compressive stress is formed entirely on the silicon substrate 1.

The fourth stress-having film 23 is comprised of an electrically insulating film having compressive stress. For instance, the fourth stress-having film 23 is comprised of a silicon nitride film formed by plasma-enhanced chemical vapor deposition.

Though not illustrated, for instance, a thin silicon oxide film (about 10 nanometers thick or thinner) may be formed below the fourth stress-having film 23 as an etching stopper film for an etching step to be carried out later, if necessary.

Then, there is formed a resist film 47 by photolithography as an etching mask for etching the fourth stress-having film 23. Then, the fourth stress-having film 23 is removed by dry etching in a region in which the n-channel type MOSFET 101 is to be fabricated. The structure at this stage is illustrated in FIG. 19D.

Then, after the resist film 47 was removed, the interlayer insulating film 31 is formed. Thus, there is obtained the structure illustrated in FIG. 19E.

Thereafter, a contact hole is formed, and then, a contact plug is formed in the contact hole. Then, necessary wires are arranged on the contact plug.

In the above-mentioned method, the third stress-having film 21 in the n-channel type field effect transistor 101 is first formed, and then, the fourth stress-having film 23 in the p-channel type field effect transistor 201 is formed. In contrast, the fourth stress-having film 23 may be first formed, and then, the third stress-having film 21 may be formed.

### First Variant of Eighth Exemplary Embodiment

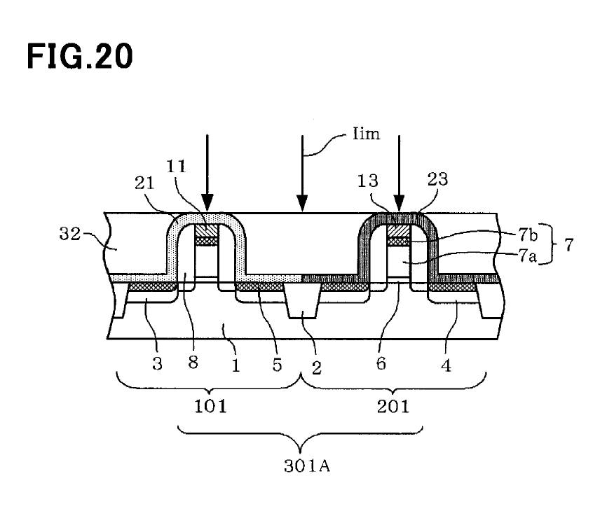

FIG. 20 is a cross-sectional view of a CMOSFET 301A in accordance with a first variant of the eighth exemplary embodiment.

The CMOSFET 301A in accordance with the present variant is structurally different from the CMOSFET 301 in accordance with the eighth exemplary embodiment, illustrated in FIG. 19E, in that a portion of the third stress-having film 21 disposed on the first stress-having film 11, and a portion of the fourth stress-having film 23 disposed on the second stress-having film 13 are formed as a stress-relaxing portion. The third stress-having film 21 and the fourth stress-having film 23 do not have stress in each of the stress-relaxing portions, that is, on the first stress-having film 11 and the second stress-having film 13, respectively.

As illustrated in FIG. 20, the stress-relaxing portion is formed by carrying out ion implantation Iim to portions of the third stress-having film 21 and the fourth stress-having film 23 disposed above the gate electrode 7 to thereby relax stress in the portions.

The CMOSFET 301A in accordance with the present variant is structurally identical with the CMOSFET 301 in accordance with the eighth exemplary embodiment except including the stress-relaxing portions. Accordingly, parts or elements that correspond to those of the CMOSFET 301 in accordance with the eighth exemplary embodiment have been provided with the same reference numerals, and are not explained hereinbelow.

In the CMOSFET 301 in accordance with the eighth exemplary embodiment, the third stress-having film 21 having tensile stress, formed on the first stress-having film 11 having compressive stress, imparts compressive stress to a channel, and the fourth stress-having film 23 having compressive stress, formed on the second stress-having film 13 having tensile stress, imparts tensile stress to a channel.

In contrast, in the CMOSFET 301A in accordance with the present variant, since the third stress-having film 21 and the fourth stress-having film 23 are designed not to have stress on the first stress-having film 11 and the second stress-having film 13, respectively, compressive or tensile stress is not imparted to a channel.

Accordingly, the CMOSFET 301A in accordance with the present variant can distort a channel to a higher degree than the CMOSFET 301 in accordance with the eighth exemplary embodiment, resulting in that mobility of electrons can be further enhanced in the n-channel type MOSFET 101, and mobility of holes can be further enhanced in the p-channel type MOSFET 201, relative to the CMOSFET 301 in accordance with the eighth exemplary embodiment.

A method of fabricating the CMOSFET 301A in accordance with the present variant is identical with a method of fabricating the first variant of the second exemplary embodiment or the first variant of the fifth exemplary embodiment.

The second and third variants of the n-channel type MOSFET in accordance with the second exemplary embodiment may be selected as a variant of the CMOSFET 301 in accordance with the eighth exemplary embodiment.

Specifically, similarly to the n-channel type MOSFET 101B (FIG. 7) in accordance with the second variant of the second exemplary embodiment, the third stress-having film 21 and the fourth stress-having film 23 may be removed by chemical mechanical polishing in portions higher than the first stress-having film 11 and the second film-having film 13, respectively.

Similarly to the n-channel type MOSFET 101C (FIG. 8) in accordance with the third variant of the second exemplary embodiment, after forming the third stress-having film 21 and the fourth stress-having film 23 to have a thickness higher than a surface of the first stress-having film 11 and a surface of the second stress-having film 13, respectively, the third stress-having film 21 and the fourth stress-having film 23 may be polished until a surface of the first stress-having film 11 and a surface of the second stress-having film 13 appear, respectively.

### Ninth Exemplary Embodiment

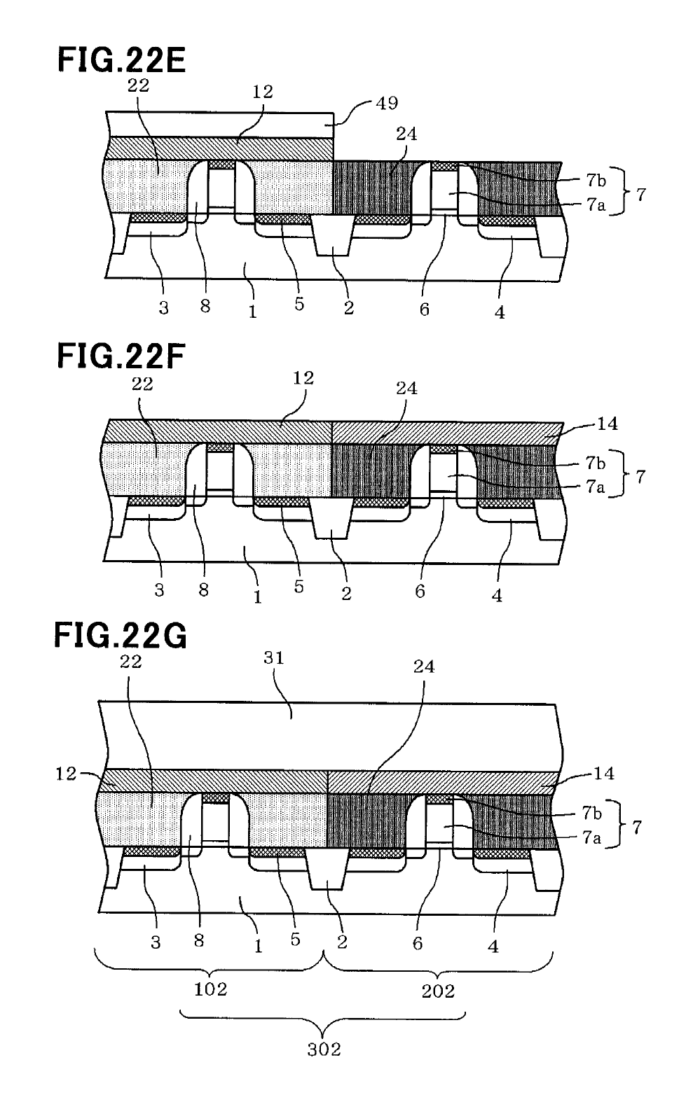

FIG. 22G is a cross-sectional view of a CMOSFET 302 in accordance with the ninth exemplary embodiment of the present invention.

The CMOSFET 302 in accordance with the present exemplary embodiment is designed to include the n-channel type MOSFET 102 in accordance with the third exemplary embodiment, illustrated in FIG. 9D, and the p-channel type MOSFET 202 in accordance with the sixth exemplary embodiment, illustrated in FIG. 14.

The n-channel type MOSFET 102 as a part of the CMOSFET 302 in accordance with the present exemplary embodiment is comprised of a silicon substrate 1, device separation regions 2 formed at a surface of the silicon substrate 1, a gate insulating film 6 formed on a surface of the silicon substrate 1 in a region sandwiched between the device separation regions 2, a gate electrode 7 having a two-layered structure including a silicon film 7a and a silicide layer 7b both formed on the gate insulating film 6, n-type impurity diffusing layers 3 formed at a surface of the silicon substrate 1 and making source/drain regions, silicide layers 5 formed on the n-type impurity diffusing layers 3, a sidewall spacer 8 covering sidewalls of the gate insulating film 6 and the gate electrode 7 therewith, a fifth stress-having film 22 having the same height at that of the gate electrode 7, covering source/drain regions of the n-channel type MOSFET 102 therewith, and having tensile stress, a sixth stress-having film 12 formed on both the gate electrode 7 and the fifth stress-having film 22, and having compressive film 12, and an interlayer insulating film 31 being formed entirely on the sixth stress-having film 12.

The p-channel type MOSFET 202 as a part of the CMOSFET 302 in accordance with the present exemplary embodiment is comprised of a silicon substrate 1, device separation regions 2 formed at a surface of the silicon substrate 1, a gate insulating film 6 formed on a surface of the silicon substrate 1 in a region sandwiched between the device separation regions 2, a gate electrode 7 having a two-layered structure including a silicon film 7a and a silicide layer 7b both formed on the gate insulating film 6, p-type impurity diffusing layers 4 formed at a surface of the silicon substrate 1 and making source/drain regions, silicide layers 5 formed on the p-type impurity diffusing layers 4, a sidewall spacer 8 covering sidewalls of the gate insulating film 6 and the gate electrode 7 therewith, a seventh stress-having film 24 having the same height at that of the gate electrode 7, covering source/drain regions of the p-channel type MOSFET 202 therewith, and having compressive stress, an eighth stress-having film 14 formed on both the gate electrode 7 and the seventh stress-having film 24, and having tensile film 12, and an interlayer insulating film 31 being formed entirely on the eighth stress-having film 14.

In the n-channel type MOSFET 102 as a part of the CMOSFET 302 in accordance with the present exemplary embodiment, the fifth stress-having film 22 having tensile stress therein is designed to have almost the same height as that of the gate electrode 7, and the sixth stress-having film 12 having compressive stress is formed on the fifth stress-having film 22.

In the p-channel type MOSFET 202 as a part of the CMOSFET 302 in accordance with the present exemplary embodiment, the seventh stress-having film 24 having compressive stress therein is designed to have almost the same height as that of the gate electrode 7, and the eighth stress-having film 12 having tensile stress is formed on the seventh stress-having film 24.

Thus, in the CMOSFET 302 in accordance with the present exemplary embodiment, since the fifth stress-having film 22 having tensile stress therein and the seventh stress-having film 24 having compressive stress therein are formed thick both around the gate electrode 7 and on the source/drain regions, high tensile and compressive distortion are applied to a channel, resulting in significant enhancement in mobility of carriers (electrons and holes) in channel regions of the n-channel type MOSFET 102 and the p-channel type MOSFET 202.

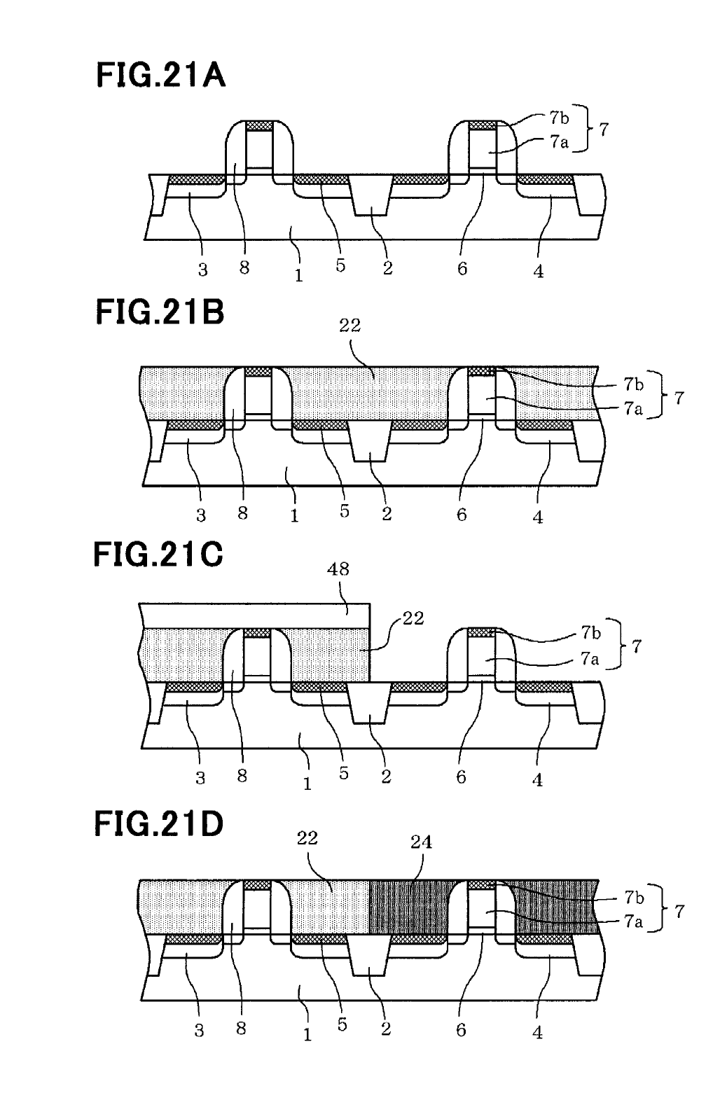

FIGS. 21A to 21D and FIGS. 22E to 22G are cross-sectional views showing steps to be carried out in a method of fabricating the CMOSFET 302 in accordance with the present exemplary embodiment.

Hereinbelow is explained a method of fabricating the CMOSFET 302 in accordance with the present exemplary embodiment, with reference to FIGS. 21A to 21D and FIGS. 22E to 22G.

Similarly to a method of fabricating a related MOSFET, the device separation regions 2 are formed at a surface of the silicon substrate 1. Then, the gate insulating film 6 is formed on the silicon substrate in a region surrounded by the device separation regions 2. Then, the silicon film 7a patterned into a gate electrode is formed on the gate insulating film 6. Then, by carrying out steps of implanting ions into the silicon substrate 1 to form shallow source/drain regions, forming the sidewall spacer 8, implanting ions into the silicon substrate 1 to form deep source/drain regions, annealing for activating the impurities, and forming the silicide layers 5 and 7b, there is obtained the structure illustrated in FIG. 21A.

Then, the fifth stress-having film 22 having tensile stress therein is formed so as to have a thickness greater than a thickness of the silicon film 7a.

Then, the fifth stress-having film 22 is polished by chemical mechanical polishing until an upper surface of the gate electrode 7 appears. The structure at this stage is illustrated in FIG. 21B.

The fifth stress-having film 22 is comprised of an electrically insulating film having tensile stress therein. For instance, the fifth stress-having film 22 is comprised of a silicon nitride film formed by thermochemical vapor deposition or atomic layer deposition.

Though not illustrated, for instance, a thin silicon oxide film (about 10 nanometers thick or thinner) may be formed below the fifth stress-having film 22 as a protection film for avoiding the transistor from being damaged in an etching step to be carried out later, if necessary.

Then, there is formed a resist film 48 by photolithography as an etching mask for etching the fifth stress-having film 22. Then, the fifth stress-having film 22 together with the above-mentioned protection film (if necessary) is removed by dry etching in a region in which the p-channel type MOSFET 202 is to be fabricated. The structure at this stage is illustrated in FIG. 21C.

After removal of the resist film 48, the seventh stress-having film 24 having compressive stress therein is formed so as to have a thickness greater than a thickness of the silicon film 7a. Then, the seventh stress-having film 24 is polished by chemical mechanical polishing until an upper surface of the gate electrode 7 appears. The structure at this stage is illustrated in FIG. 21D.

As an alternative, a resist mask may be formed by known photolithography, and the seventh stress-having film 24 is dry-etched through the use of the resist mask to thereby remove the seventh stress-having film 24 in a portion disposed in a region in which the n-channel type MOSFET 102 is to be fabricated. By doing so, there can be obtained the structure illustrated in FIG. 21D.

The seventh stress-having film 24 is comprised of an electrically insulating film having compressive stress. For instance, the seventh stress-having film 24 is comprised of a silicon nitride film formed by plasma-enhanced chemical vapor deposition.

Then, the sixth stress-having film 12 having compressive stress therein is formed entirely on the silicon substrate.

The sixth stress-having film 12 is comprised of an electrically insulating film having compressive stress. For instance, the sixth stress-having film 12 is comprised of a silicon nitride film formed by plasma-enhanced chemical vapor deposition.

The sixth stress-having film 12 may be composed of materials mentioned above as materials of which the first stress-having film 11 is composed in the first exemplary embodiment.

Though not illustrated, for instance, a thin silicon oxide film (about 10 nanometers thick or thinner) may be formed below the sixth stress-having film 12 as an etching stopper film for an etching step to be carried out later, if necessary.

Then, there is formed a resist film 49 by photolithography as an etching mask for etching the sixth stress-having film 12. Then, the sixth stress-having film 12 together with the etching stopper film (if necessary) is removed by dry etching in a region in which the p-channel type MOSFET 202 is to be fabricated. The structure at this stage is illustrated in FIG. 22E.

Then, after the resist film 49 was removed, the eighth stress-having film 14 having tensile stress therein is formed entirely on the silicon substrate.

Then, the eighth stress-having film 14 is polished by chemical mechanical polishing until the sixth stress-having film 12 and the eighth stress-having film 14 come to have a predetermined height above the gate electrode 7. The structure at this stage is illustrated in FIG. 22F.

As an alternative, a resist mask may be formed by known photolithography, and the eighth stress-having film 14 may be removed through the use of the resist mask in a region in which the n-channel type MOSFET 102 is to be fabricated. By doing so, there can be obtained the structure illustrated in FIG. 22F.

The eighth stress-having film 14 is comprised of an electrically insulating film having tensile stress. For instance, the eighth stress-having film 14 is comprised of a silicon nitride film formed by thermochemical vapor deposition or atomic layer deposition.

The eighth stress-having film 14 may be composed of materials mentioned above as materials of which the first stress-having film 11 is composed in the first exemplary embodiment.

Then, there is formed the interlayer insulating film 31. Thus, there is obtained the structure illustrated in FIG. 22G.

Thereafter, a contact hole is formed, and then, a contact plug is formed in the contact hole. Then, necessary wires are arranged on the contact plug.

In the above-mentioned method, the fifth stress-having film 22 in the n-channel type MOSFET 102 is firstly formed, the seventh stress-having film 24 in the p-channel type MOSFET 202 is secondly formed, the sixth stress-having film 12 in the n-channel type MOSFET 102 is thirdly formed, and the eighth stress-having film 14 in the p-channel type MOSFET 202 is fourthly formed. It should be noted that an order of forming the above-mentioned stress-having films is not to be limited to the above-mentioned order.

An order of forming the fifth stress-having film 22 and an order of forming the seventh stress-having film 24 may be switched to each other. Furthermore, an order of forming the sixth stress-having film 12 and an order of forming the eighth stress-having film 14 may be switched to each other.

For instance, the seventh stress-having film 24 in the p-channel type MOSFET 202 may be firstly formed, the fifth stress-having film 22 in the n-channel type MOSFET 102 may be secondly formed, the eighth stress-having film 14 in the p-channel type MOSFET 202 may be thirdly formed, and the sixth stress-having film 12 in the n-channel type MOSFET 102 may be fourthly formed.

In addition, similarly to the first variant of the third exemplary embodiment, illustrated in FIG. 10, the sixth stress-having film 12 and the eighth stress-having film 14 may be formed only on the gate electrodes 7 of the n-channel type MOSFET 102 and the p-channel type MOSFET 202, respectively, in the CMOSFET 302 in accordance with the present exemplary embodiment.

In the above-mentioned case, the sixth stress-having film 12 and the eighth stress-having film 14 are formed by depositing the sixth stress-having film 12 and the eighth stress-having film 14 entirely on the gate electrode 7, the fifth stress-having film 22, and the seventh stress-having film 24, and patterning the sixth stress-having film 12 and the eighth stress-having film 14 by photolithography such that the sixth stress-having film 12 and the eighth stress-having film 14 remain only on the gate electrodes 7.

### Tenth Exemplary Embodiment

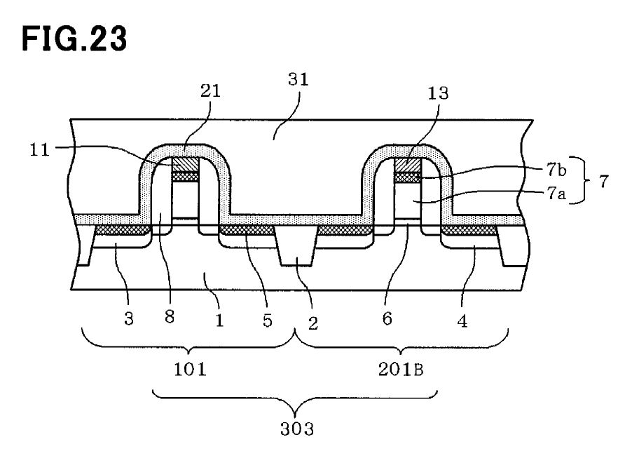

FIG. 23 is a cross-sectional view of a CMOSFET 303 in accordance with the tenth exemplary embodiment of the present invention.

In a CMOSFET, performance in one of an n-channel type MOSFET and a p-channel type MOSFET is sometimes required to be higher than another in accordance with a use thereof. Furthermore, in light of a trade-off relation between readiness of fabrication and performance of a MOSFET, a weight is sometimes put on readiness of fabrication rather than performance in one of n- and p-channel MOSFETs.

The tenth exemplary embodiment and subsequent exemplary embodiments are prepared for such a use.

The CMOSFET 303 in accordance with the present exemplary embodiment is designed to include the n-channel type MOSFET 101 in accordance with the second exemplary embodiment, illustrated in FIG. 5B, and a p-channel type MOSFET 201B.

Whereas the fourth stress-having film 23 having compressive stress is formed covering the p-channel type MOSFET 201 therewith in the CMOSFET 301 in accordance with the eighth exemplary embodiment, illustrated in FIG. 19E, a third stress-having film 21 having tensile stress therein is formed covering the p-channel type MOSFET 201B therewith in the CMOSFET 303 in accordance with the present exemplary embodiment. Specifically, in the CMOSFET 303 in accordance with the present exemplary embodiment, the third stress-having film 21 having tensile stress therein is formed to cover both the n-channel type MOSFET 101 and the p-channel type MOSFET 201B therewith.

The CMOSFET 303 in accordance with the present exemplary embodiment is structurally identical with the CMOSFET 301 in accordance with the eighth exemplary embodiment, illustrated in FIG. 19E, except that the p-channel type MOSFET 201B is designed to include the third stress-having film 21 in place of the fourth stress-having film 23. Accordingly, parts or elements that correspond to those of the CMOSFET 301 in accordance with the eighth exemplary embodiment have been provided with the same reference numerals, and are not explained hereinbelow.

Hereinbelow are explained the advantage provided by the CMOSFET 303 in accordance with the present exemplary embodiment.

In the n-channel type MOSFET 101, similarly to the eighth exemplary embodiment, since the first stress-having film 11 formed on the gate electrode 7 and having compressive stress imparts tensile stress to a channel, and further, the third stress-having film 21 covering the gate electrode 7, the sidewall spacer 8, and the source/drain regions therewith, and having tensile stress imparts tensile stress to a channel, the channel is distorted in a direction in which the tensile stress is applied, resulting in enhancement in mobility of electrons.

Hereinbelow is explained a method of fabricating the CMOSFET 303 in accordance with the present exemplary embodiment.

A method of fabricating the CMOSFET 303 can be obtained by omitting both the step of removing the third stress-having film 21 having tensile stress therein, in a region in which the p-channel type MOSFET 201 is fabricated, and the step of forming the fourth stress-having film 23 having compressive stress, and removing the fourth stress-having film 23 in a region in which the n-channel type MOSFET 101 is fabricated, out of a method of fabricating the CMOSFET 301 in accordance with the eighth exemplary embodiment. That is, the CMOSFET 303 in accordance with the present exemplary embodiment can be fabricated by carrying out the steps illustrated in FIGS. 18A and 18B.

The CMOSFET 303 in accordance with the present exemplary embodiment has three variants.

In the CMOSFET 303 in accordance with the present exemplary embodiment, similarly to the first variant of the eighth exemplary embodiment illustrated in FIG. 20, the third stress-having film 21 may be designed to have a stress-relaxing portion above the gate electrode 7 in each of the n-channel type MOSFET 101 and the p-channel type MOSFET 201B.

The third stress-having film 21 has no stress in the stress-relaxing portion, that is, on both the first stress-having film 11 and the second stress-having film 13.

The stress-relaxing portion can be formed by carrying out ion implantation Iim into a portion of the third stress-having film 21 disposed above the gate electrode 7 to thereby relax stress in the portion.

As an alternative, similarly to the first variant of the second exemplary embodiment illustrated in FIG. 6B, the CMOSFET 303 in accordance with the present exemplary embodiment may be designed to include a cut-out as a stress-relaxing portion in the third stress-having film 21 above each of the gate electrode 7 in each of the n-channel type MOSFET 101 and the p-channel type MOSFET 201B.

In the CMOSFET 303 in accordance with the present exemplary embodiment, similarly to the third variant of the second exemplary embodiment illustrated in FIG. 8, the third stress-having film 21 may be designed to have a height reaching a height of upper surfaces of the first stress-having film 11 and the second stress-having film 13.

In the CMOSFET 303 in accordance with the present exemplary embodiment, the third stress-having film 21 having tensile stress therein, formed on the first stress-having film 11 having compressive stress, imparts compressive distortion to a channel. In contrast, in the above-mentioned three variants, since the third stress-having film 21 formed on the first stress-having film 11 has no stress therein, or the third stress-having film 21 is not formed, compressive distortion is not imparted to a channel.

Accordingly, the above-mentioned three variants can distort a channel to a higher degree than the CMOSFET 303 in accordance with the present exemplary embodiment, resulting in further enhancement in mobility of electrons in a channel region of the n-channel type MOSFET.

A method of fabricating the CMOSFET in accordance with the above-mentioned first variant is identical with a method of fabricating the first variant of the eighth exemplary embodiment.

### Eleventh Exemplary Embodiment

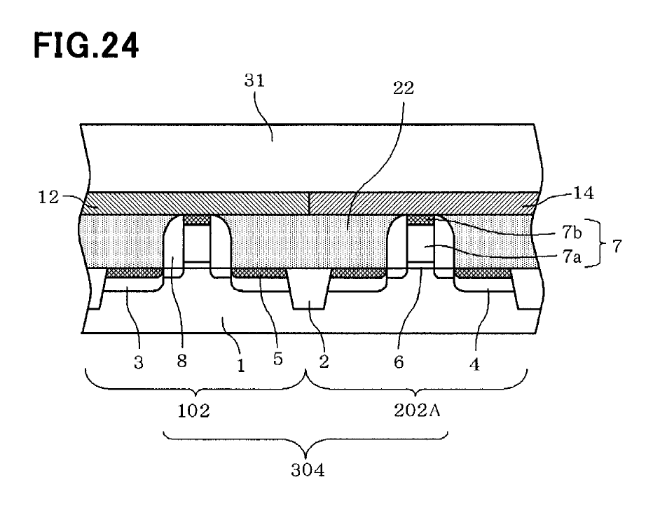

FIG. 24 is a cross-sectional view of a CMOSFET 304 in accordance with the eleventh exemplary embodiment of the present invention.

The CMOSFET 304 in accordance with the present exemplary embodiment is designed to include the n-channel type MOSFET 102 in accordance with the third exemplary embodiment, illustrated in FIG. 9D, and a p-channel type MOSFET 202A.

The CMOSFET 304 in accordance with the present exemplary embodiment is structurally different from the CMOSFET 302 in accordance with the ninth exemplary embodiment, illustrated in FIG. 22G, in that the p-channel type MOSFET 202A is designed to include a fifth stress-having film 22 having tensile stress therein, in place of the seventh stress-having film 24 having compressive stress.

Specifically, the CMOSFET 304 in accordance with the present exemplary embodiment is designed to include the fifth stress-having film 22 having tensile stress therein, and covering both the n-channel type MOSFET 102 and the p-channel type MOSFET 202A therewith.

The CMOSFET 304 in accordance with the present exemplary embodiment is structurally identical with the CMOSFET 302 in accordance with the ninth exemplary embodiment except in that the p-channel type MOSFET 202A is designed to include the fifth stress-having film 22 in place of the seventh stress-having film 24. Accordingly, parts or elements that correspond to those of the CMOSFET 302 in accordance with the ninth exemplary embodiment have been provided with the same reference numerals, and are not explained hereinbelow.

Hereinbelow are explained the advantages provided by the CMOSFET 304 in accordance with the present exemplary embodiment.

In the CMOSFET 304 in accordance with the present exemplary embodiment, since the fifth stress-having film 22 having tensile stress therein and covering the gate electrode 7, the sidewall spacer 8, and the source/drain regions therewith is formed thick, high tensile distortion is applied to a channel. Furthermore, since the sixth stress-having film 12 having compressive stress and being formed on the gate electrode 7 in the n-channel type MOSFET 102 facilitates tensile distortion of a channel, it is possible to significantly enhance mobility of electrons in a channel region of the n-channel type MOSFET 102.

Hereinbelow is explained a method of fabricating the CMOSFET 304 in accordance with the present exemplary embodiment.

A method of fabricating the CMOSFET 304 in accordance with the present exemplary embodiment can be obtained by omitting both the step of removing the fifth stress-having film 22 having tensile stress therein, in a region in which the p-channel type MOSFET 202 is fabricated, and the step of forming the seventh stress-having film 24 having compressive stress, and removing the seventh stress-having film 24 in a region in which the n-channel type MOSFET 102 is fabricated, out of a method of fabricating the CMOSFET 302 in accordance with the ninth exemplary embodiment.

That is, the CMOSFET 304 in accordance with the present exemplary embodiment can be fabricated by omitting the steps illustrated in FIGS. 21C and 21D, and carrying out the steps illustrated in FIGS. 22E, 22F and 22G after carrying out the step illustrated in FIG. 21B.

In the CMOSFET 304 in accordance with the present exemplary embodiment, similarly to the n-channel type MOSFET 102A in accordance with the first variant of the third exemplary embodiment, illustrated in FIG. 10, the sixth stress-having film 12 and the eighth stress-having film 14 may be formed on each of the gate electrodes 7.

### Twelfth Exemplary Embodiment

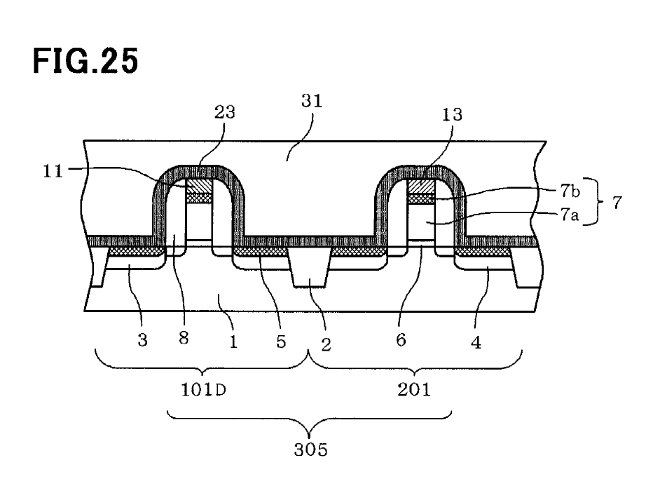

FIG. 25 is a cross-sectional view of a CMOSFET 305 in accordance with the twelfth exemplary embodiment of the present invention.

The CMOSFET 305 in accordance with the present exemplary embodiment is designed to include an n-channel type MOSFET 101D, and the p-channel type MOSFET 201 in accordance with the fifth exemplary embodiment, illustrated in FIG. 12.

The CMOSFET 305 in accordance with the present exemplary embodiment is structurally different from the CMOSFET 303 in accordance with the tenth exemplary embodiment, illustrated in FIG. 23, in that a fourth stress-having film 23 having compressive stress therein is formed in place of the third stress-having film 21 having tensile stress therein in both of the n-channel type MOSFET 101D and the p-channel type MOSFET 201.

The CMOSFET 305 in accordance with the present exemplary embodiment is structurally identical with the CMOSFET 303 in accordance with the tenth exemplary embodiment, illustrated in FIG. 23, except in that the CMOSFET 305 is designed to include the fourth stress-having film 23 in place of the third stress-having film 21. Accordingly, parts or elements that correspond to those of the CMOSFET 303 in accordance with the tenth exemplary embodiment have been provided with the same reference numerals, and are not explained hereinbelow.

Hereinbelow are explained the advantages provided by the CMOSFET 305 in accordance with the present exemplary embodiment.

In the p-channel type MOSFET 201, similarly to the eighth exemplary embodiment, since the second stress-having film 13 having tensile stress therein and being formed on the gate electrode 7 imparts compressive stress to a channel. Furthermore, the fourth stress-having film 23 covering the gate electrode 7, the sidewall spacer 8, and the source/drain regions therewith imparts compressive stress to a channel. Accordingly, a channel is much distorted in a direction in which the compressive stresses are applied, resulting in significant enhancement in mobility of holes.

A method of fabricating the CMOSFET 305 in accordance with the present exemplary embodiment is fundamentally identical with a method of fabricating the CMOSFET 303 in accordance with the seventh exemplary embodiment, illustrated in FIG. 23. Specifically, a method of fabricating the CMOSFET 305 in accordance with the present exemplary embodiment is different from a method of fabricating the CMOSFET 303 in accordance with the seventh exemplary embodiment in that a material of which the fourth stress-having film 23 is composed is used in place of a material of which the third stress-having film 21 is composed.

The CMOSFET 305 in accordance with the present exemplary embodiment has three variants.

In the CMOSFET 305 in accordance with the present exemplary embodiment, similarly to the first variant of the eighth exemplary embodiment illustrated in FIG. 20, the fourth stress-having film 23 may be designed to have a stress-relaxing portion above the gate electrode 7 in each of the n-channel type MOSFET 101 and the p-channel type MOSFET 201.

The fourth stress-having film 23 has no stress in the stress-relaxing portion, that is, on both the first stress-having film 11 and the second stress-having film 13.

The stress-relaxing portion can be formed by carrying out ion implantation Iim into a portion of the fourth stress-having film 23 disposed above the gate electrode 7 to thereby relax stress in the portion.

As an alternative, similarly to the first variant of the second exemplary embodiment illustrated in FIG. 6B, the CMOSFET 305 in accordance with the present exemplary embodiment may be designed to include a cut-out as a stress-relaxing portion in the fourth stress-having film 23 above each of the gate electrode 7 in each of the n-channel type MOSFET 101 and the p-channel type MOSFET 201.

In the CMOSFET 305 in accordance with the present exemplary embodiment, similarly to the third variant of the second exemplary embodiment illustrated in FIG. 8, the fourth stress-having film 23 may be designed to have a height reaching a height of upper surfaces of the first stress-having film 11 and the second stress-having film 13.

In the CMOSFET 305 in accordance with the present exemplary embodiment, the fourth stress-having film 23 having compressive stress therein, formed on the second stress-having film 13 having tensile stress, imparts tensile distortion to a channel. In contrast, in the above-mentioned three variants, since the fourth stress-having film 23 formed on the second stress-having film 13 has no stress therein, or the fourth stress-having film 23 is not formed on the second stress-having film 13, tensile distortion is not imparted to a channel.

Accordingly, the above-mentioned three variants can distort a channel to a higher degree than the CMOSFET 305 in accordance with the present exemplary embodiment, resulting in further enhancement in mobility of holes in a channel region of the p-channel type MOSFET 201.

A method of fabricating the CMOSFET in accordance with the above-mentioned first variant is identical with a method of fabricating the first variant of the eighth exemplary embodiment.

### Thirteenth Exemplary Embodiment

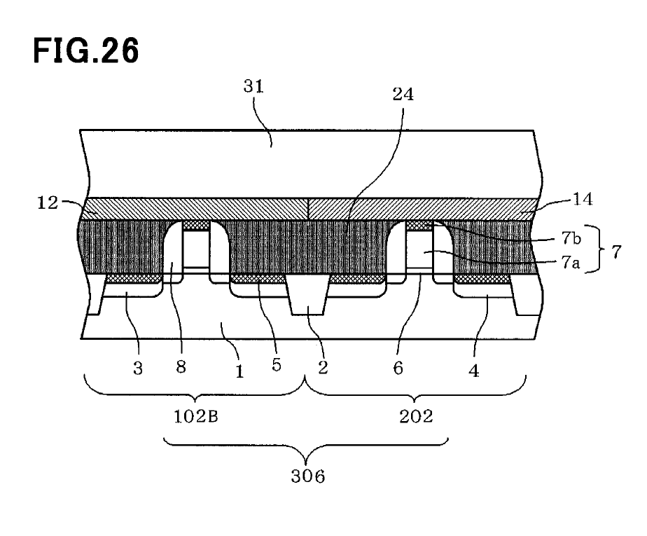

FIG. 26 is a cross-sectional view of a CMOSFET 306 in accordance with the thirteenth exemplary embodiment of the present invention.

The CMOSFET 306 in accordance with the present exemplary embodiment is designed to include an n-channel type MOSFET 102B, and the p-channel type MOSFET 202 in accordance with the sixth exemplary embodiment, illustrated in FIG. 14.

The CMOSFET 306 in accordance with the present exemplary embodiment is structurally different from the CMOSFET 304 in accordance with the eleventh exemplary embodiment, illustrated in FIG. 24, in that a seventh stress-having film 24 having compressive stress therein is formed in place of the fifth stress-having film 22 having tensile stress therein in both of the n-channel type MOSFET 102B and the p-channel type MOSFET 202.

Specifically, the CMOSFET 306 in accordance with the present exemplary embodiment is designed to include the seventh stress-having film 24 having compressive stress therein, and covering both the n-channel type MOSFET 102B and the p-channel type MOSFET 202 therewith.

The CMOSFET 306 in accordance with the present exemplary embodiment is structurally identical with the CMOSFET 304 in accordance with the eleventh exemplary embodiment except in that both of the n-channel type MOSFET 102B and the p-channel type MOSFET 202 are designed to include the seventh stress-having film 24 in place of the fifth stress-having film 22. Accordingly, parts or elements that correspond to those of the CMOSFET 304 in accordance with the eleventh exemplary embodiment have been provided with the same reference numerals, and are not explained hereinbelow.

Hereinbelow are explained the advantages provided by the CMOSFET 306 in accordance with the present exemplary embodiment.

In the CMOSFET 306 in accordance with the present exemplary embodiment, since the seventh stress-having film 24 having compressive stress therein is formed thick on the gate electrode 7, the sidewall spacer 8, and the source/drain regions, high compressive distortion is applied to a channel in the p-channel type MOSFET 202. Furthermore, since the eighth stress-having film 14 having tensile stress and being formed on the gate electrode 7 in the p-channel type MOSFET 202 facilitates compressive distortion of a channel, it is possible to significantly enhance mobility of holes in a channel region of the p-channel type MOSFET 202.

A method of fabricating the CMOSFET 306 in accordance with the present exemplary embodiment is fundamentally identical with a method of fabricating the CMOSFET 304 in accordance with the eleventh exemplary embodiment, illustrated in FIG. 24. Specifically, a method of fabricating the CMOSFET 306 in accordance with the present exemplary embodiment is different from a method of fabricating the CMOSFET 304 in accordance with the eleventh exemplary embodiment in that a material of which the seventh stress-having film 24 is composed is used in place of a material of which the fifth stress-having film 22 is composed.

In the CMOSFET 306 in accordance with the present exemplary embodiment, similarly to the n-channel type MOSFET 102A in accordance with the first variant of the third exemplary embodiment, illustrated in FIG. 10, the sixth stress-having film 12 and the eighth stress-having film 14 may be formed only on each of the gate electrodes 7.

### Fourteenth Exemplary Embodiment

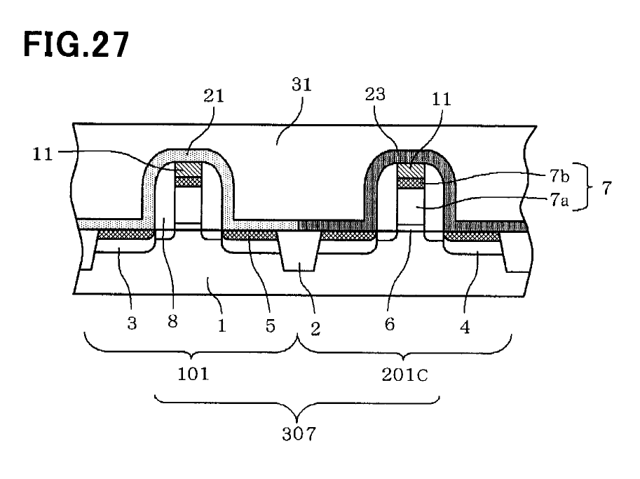

FIG. 27 is a cross-sectional view of a CMOSFET 307 in accordance with the fourteenth exemplary embodiment of the present invention.

The CMOSFET 307 in accordance with the present exemplary embodiment is designed to include the n-channel type MOSFET 101 in accordance with the second exemplary embodiment, illustrated in FIG. 5B, and a p-channel type MOSFET 201C.

The CMOSFET 307 in accordance with the present exemplary embodiment is structurally different from the CMOSFET 301 in accordance with the eighth exemplary embodiment, illustrated in FIG. 19E, in that the p-channel type MOSFET 201C is designed to include a first stress-having film 11 having compressive stress therein in place of the second stress-having film 13 having tensile stress therein.

The CMOSFET 307 in accordance with the present exemplary embodiment is structurally identical with the CMOSFET 301 in accordance with the eighth exemplary embodiment, illustrated in FIG. 19E, except in that the p-channel type MOSFET 201C includes the first stress-having film 11 in place of the second stress-having film 13. Accordingly, parts or elements that correspond to those of the CMOSFET 301 in accordance with the eighth exemplary embodiment have been provided with the same reference numerals, and are not explained hereinbelow.

Hereinbelow are explained the advantages provided by the CMOSFET 307 in accordance with the present exemplary embodiment.

In the n-channel type MOSFET 101, similarly to the eighth exemplary embodiment, since the first stress-having film 11 having compressive stress therein and being formed on the gate electrode 7 imparts tensile stress to a channel. Furthermore, the third stress-having film 21 having tensile stress therein, and covering the gate electrode 7, the sidewall spacer 8, and the source/drain regions therewith imparts tensile stress to a channel. Accordingly, a channel in the n-channel type MOSFET 101 is much distorted in a direction in which the tensile stresses are applied, resulting in significant enhancement in mobility of electrons.

Hereinbelow is explained a method of fabricating the CMOSFET 307 in accordance with the present exemplary embodiment.

A method of fabricating the CMOSFET 307 in accordance with the present exemplary embodiment can be obtained by omitting both the step of forming the second stress-having film 13 having tensile stress therein, in a region in which the p-channel type MOSFET 201C is fabricated (FIG. 16B), and the step of removing the second stress-having film 13 in a region in which the n-channel type MOSFET 101 is fabricated (FIG. 16C), out of a method of fabricating the CMOSFET 301 in accordance with the eighth exemplary embodiment.

That is, a method of fabricating the CMOSFET 301 in accordance with the eighth exemplary embodiment has to include a plurality of steps to form the first stress-having film 11 and the second stress-having film 13 in the n-channel type MOSFET 101 and the p-channel type MOSFET 201C, respectively. In contrast, a method of fabricating the CMOSFET 307 in accordance with the present exemplary embodiment makes it possible to form the first stress-having film 11 in each of the n-channel type MOSFET 101 and the p-channel type MOSFET 201C in a single step.

The CMOSFET 307 in accordance with the present exemplary embodiment has three variants.

In the CMOSFET 307 in accordance with the present exemplary embodiment, similarly to the first variant of the eighth exemplary embodiment illustrated in FIG. 20, each of the third stress-having film 21 and the fourth stress-having film 23 may be designed to have a stress-relaxing portion above the gate electrode 7 in each of the n-channel type MOSFET 101 and the p-channel type MOSFET 201C.

The third stress-having film 21 and fourth stress-having film 23 have no stress in the stress-relaxing portion, that is, on the first stress-having film 11.

The stress-relaxing portion can be formed by carrying out ion implantation Iim into portions of the third stress-having film 21 and the fourth stress-having film 23 disposed above the gate electrode 7 to thereby relax stress in the portions.

As an alternative, similarly to the first variant of the second exemplary embodiment illustrated in FIG. 6B, the CMOSFET 307 in accordance with the present exemplary embodiment may be designed to include a cut-out as a stress-relaxing portion in the third stress-having film 21 and the fourth stress-having film 23 above each of the gate electrode 7 in each of the n-channel type MOSFET 101 and the p-channel type MOSFET 201C.

In the CMOSFET 307 in accordance with the present exemplary embodiment, similarly to the third variant of the second exemplary embodiment illustrated in FIG. 8, the third stress-having film 21 and the fourth stress-having film 23 may be designed to have a height reaching a height of an upper surface of the first stress-having film 11.

In the CMOSFET 307 in accordance with the present exemplary embodiment, the third stress-having film 21 having tensile stress therein and being formed on the first stress-having film 11 having compressive stress in the n-channel type MOSFET 101 imparts compressive distortion to a channel, and the fourth stress-having film 23 having compressive stress therein and being formed on the first stress-having film 11 having compressive stress in the p-channel type MOSFET 201C imparts tensile distortion to a channel.

In contrast, in the above-mentioned three variants, since the third stress-having film 21 and the fourth stress-having film 23 both formed on the first stress-having film 11 have no stress therein, or the third stress-having film 21 and the fourth stress-having film 23 are not formed on the first stress-having film 11, compressive or tensile distortion is not imparted to a channel.

Accordingly, the above-mentioned three variants can distort a channel in both of the n-channel type MOSFET 101 and the p-channel type MOSFET 201C to a higher degree than the CMOSFET 307 in accordance with the present exemplary embodiment, resulting in further enhancement in both mobility of electrons in a channel region of the n-channel type MOSFET 101 and mobility of holes in a channel region of the p-channel type MOSFET 201C.

A method of fabricating the CMOSFET in accordance with the above-mentioned first variant is identical with a method of fabricating the first variant of the eighth exemplary embodiment.

### Fifteenth Exemplary Embodiment

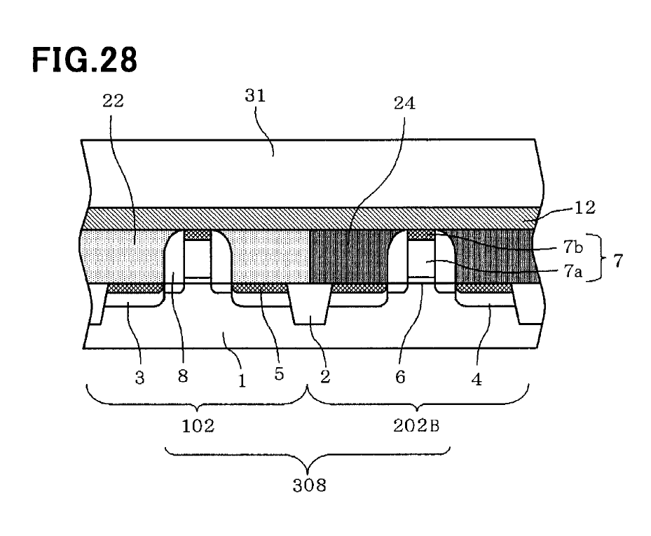

FIG. 28 is a cross-sectional view of a CMOSFET 308 in accordance with the fifteenth exemplary embodiment of the present invention.

The CMOSFET 308 in accordance with the present exemplary embodiment is designed to include the n-channel type MOSFET 102 in accordance with the third exemplary embodiment, illustrated in FIG. 9D, and a p-channel type MOSFET 202B.

The CMOSFET 308 in accordance with the present exemplary embodiment is structurally different from the CMOSFET 302 in accordance with the ninth exemplary embodiment, illustrated in FIG. 22G, in that the p-channel type MOSFET 202B is designed to include a sixth stress-having film 12 having compressive stress therein in place of the eighth stress-having film 14 having tensile stress therein.

Specifically, the CMOSFET 308 in accordance with the present exemplary embodiment is designed to include the sixth stress-having film 12 having compressive stress therein, and covering both the fifth stress-having film 22 formed in the n-channel type MOSFET 102, and the seventh stress-having film 24 formed in the p-channel type MOSFET 202B.

The CMOSFET 308 in accordance with the present exemplary embodiment is structurally identical with the CMOSFET 302 in accordance with the ninth exemplary embodiment, illustrated in FIG. 22G, except in that the n-channel type MOSFET 202B is designed to include the sixth stress-having film 12 in place of the eighth stress-having film 14. Accordingly, parts or elements that correspond to those of the CMOSFET 302 in accordance with the ninth exemplary embodiment have been provided with the same reference numerals, and are not explained hereinbelow.

Hereinbelow are explained the advantages provided by the CMOSFET 308 in accordance with the present exemplary embodiment.

In the CMOSFET 308 in accordance with the present exemplary embodiment, since the fifth stress-having film 22 having tensile stress therein is formed thick covering the gate electrode 7, the sidewall spacer 8, and the source/drain regions therewith, high tensile distortion is applied to a channel in the n-channel type MOSFET 102, resulting in significant enhancement in mobility of carriers (electrons) in the n-channel type MOSFET 102.

Furthermore, since the seventh stress-having film 24 having compressive stress is formed thick covering the gate electrode 7, the sidewall spacer 8, and the source/drain regions therewith, high compressive distortion is applied to a channel in the p-channel type MOSFET 202B, resulting in significant enhancement in mobility of carriers (holes) in the p-channel type MOSFET 202B.

A method of fabricating the CMOSFET 308 in accordance with the present exemplary embodiment can be obtained by omitting both the step of removing the sixth stress-having film 12 having compressive stress therein, in a region in which the p-channel type MOSFET 202 is fabricated, and the step of forming the eighth stress-having film 14 having tensile stress, and removing the eighth stress-having film 14 in a region in which the n-channel type MOSFET 102 is fabricated, out of a method of fabricating the CMOSFET 302 in accordance with the ninth exemplary embodiment.

That is, a method of fabricating the CMOSFET 302 in accordance with the ninth exemplary embodiment has to include a plurality of steps to form the sixth stress-having film 12 and the eighth stress-having film 14. In contrast, a method of fabricating the CMOSFET 308 in accordance with the present exemplary embodiment makes it possible to reduce a number of steps, because there is only formed the sixth stress-having film 12.

In the CMOSFET 308 in accordance with the present exemplary embodiment, similarly to the n-channel type MOSFET 102A in accordance with the first variant of the third exemplary embodiment, illustrated in FIG. 10, the sixth stress-having film 12 may be formed only on the gate electrodes 7 in the n-channel type MOSFET 102. In the p-channel type MOSFET 202B, the sixth stress-having film 12 may be left as it is.

### Sixteenth Exemplary Embodiment

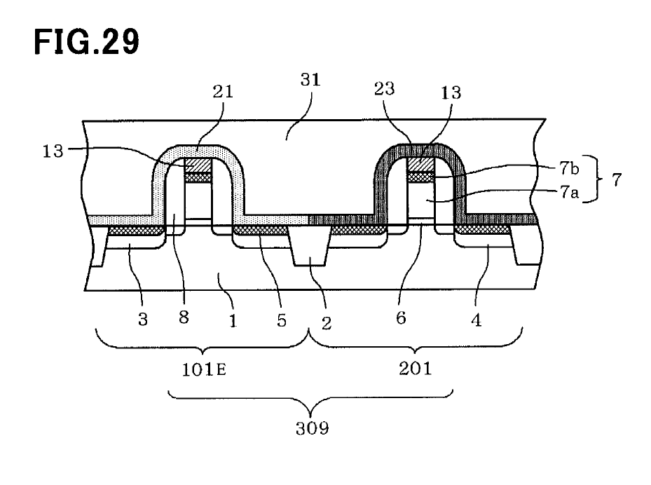

FIG. 29 is a cross-sectional view of a CMOSFET 309 in accordance with the sixteenth exemplary embodiment of the present invention.

The CMOSFET 309 in accordance with the present exemplary embodiment is designed to include an n-channel type MOSFET 101E, and the p-channel type MOSFET 201 in accordance with the fifth exemplary embodiment, illustrated in FIG. 12.

The CMOSFET 309 in accordance with the present exemplary embodiment is structurally different from the CMOSFET 301 in accordance with the eighth exemplary embodiment, illustrated in FIG. 19E, in that the n-channel type MOSFET 101E is designed to include a second stress-having film 13 having tensile stress therein in place of the first stress-having film 11 having compressive stress therein.

The CMOSFET 309 in accordance with the present exemplary embodiment is structurally identical with the CMOSFET 301 in accordance with the eighth exemplary embodiment, illustrated in FIG. 19E, except in that the n-channel type MOSFET 101E is designed to include the second stress-having film 13 in place of the first stress-having film 11. Accordingly, parts or elements that correspond to those of the CMOSFET 301 in accordance with the eighth exemplary embodiment have been provided with the same reference numerals, and are not explained hereinbelow.

Hereinbelow are explained the advantages provided by the CMOSFET 309 in accordance with the present exemplary embodiment.

In the p-channel type MOSFET 201, similarly to the eighth exemplary embodiment, since the second stress-having film 13 having tensile stress therein and being formed on the gate electrode 7 imparts compressive stress to a channel. Furthermore, the fourth stress-having film 23 having compressive stress therein, and covering the gate electrode 7, the sidewall spacer 8, and the source/drain regions therewith imparts compressive stress to a channel. Accordingly, it is possible to much distort a channel in a direction in which the compressive stresses are applied, resulting in significant enhancement in mobility of holes.

Hereinbelow is explained a method of fabricating the CMOSFET 309 in accordance with the present exemplary embodiment.

A method of fabricating the CMOSFET 309 in accordance with the present exemplary embodiment can be obtained by omitting both the step of forming the first stress-having film 11 having compressive stress therein, in a region in which the n-channel type MOSFET 101 is fabricated, and the step of removing the first stress-having film 11 in a region in which the p-channel type MOSFET 201 is fabricated, out of a method of fabricating the CMOSFET 301 in accordance with the eighth exemplary embodiment.

That is, a method of fabricating the CMOSFET 301 in accordance with the eighth exemplary embodiment has to include a plurality of steps to form the first stress-having film 11 and the second stress-having film 13 in the n-channel type MOSFET 101 and the p-channel type MOSFET 201, respectively. In contrast, a method of fabricating the CMOSFET 309 in accordance with the present exemplary embodiment makes it possible to form the second stress-having film 13 in each of the n-channel type MOSFET 101E and the p-channel type MOSFET 201 in a single step.

The CMOSFET 309 in accordance with the present exemplary embodiment has three variants.

In the CMOSFET 309 in accordance with the present exemplary embodiment, similarly to the first variant of the eighth exemplary embodiment illustrated in FIG. 20, each of the third stress-having film 21 and the fourth stress-having film 23 may be designed to have a stress-relaxing portion above the gate electrode 7 in each of the n-channel type MOSFET 101 and the p-channel type MOSFET 201.

The third stress-having film 21 and fourth stress-having film 23 have no stress in the stress-relaxing portion, that is, on the second stress-having film 13.

The stress-relaxing portion can be formed by carrying out ion implantation Iim into portions of the third stress-having film 21 and the fourth stress-having film 23 disposed above the gate electrode 7 to thereby relax stress in the portions.

As an alternative, similarly to the first variant of the second exemplary embodiment illustrated in FIG. 6B, the CMOSFET 309 in accordance with the present exemplary embodiment may be designed to include a cut-out as a stress-relaxing portion in the third stress-having film 21 and the fourth stress-having film 23 above each of the gate electrode 7 in each of the n-channel type MOSFET 101 and the p-channel type MOSFET 201.

In the CMOSFET 309 in accordance with the present exemplary embodiment, similarly to the third variant of the second exemplary embodiment illustrated in FIG. 8, the third stress-having film 21 and the fourth stress-having film 23 may be designed to have a height reaching a height of an upper surface of the second stress-having film 13.

In the CMOSFET 309 in accordance with the present exemplary embodiment, the third stress-having film 21 having tensile stress therein and being formed on the second stress-having film 13 having tensile stress in the n-channel type MOSFET 101 imparts compressive distortion to a channel, and the fourth stress-having film 23 having compressive stress therein and being formed on the second stress-having film 13 having tensile stress in the p-channel type MOSFET 201 imparts tensile distortion to a channel.

In contrast, in the above-mentioned three variants, since the third stress-having film 21 and the fourth stress-having film 23 both formed on the second stress-having film 13 have no stress therein, or the third stress-having film 21 and the fourth stress-having film 23 are not formed on the second stress-having film 13, compressive or tensile distortion is not imparted to a channel.

Accordingly, the above-mentioned three variants can distort a channel in both of the n-channel type MOSFET 101 and the p-channel type MOSFET 201 to a higher degree than the CMOSFET 309 in accordance with the present exemplary embodiment, resulting in further enhancement in both mobility of electrons in a channel region of the n-channel type MOSFET 101 and mobility of holes in a channel region of the p-channel type MOSFET 201.

A method of fabricating the CMOSFET in accordance with the above-mentioned first variant is identical with a method of fabricating the first variant of the eighth exemplary embodiment.

### Seventeenth Exemplary Embodiment

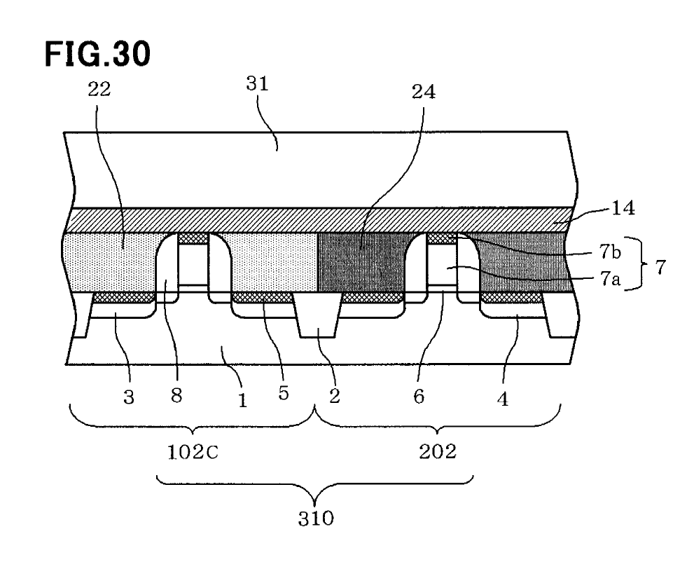

FIG. 30 is a cross-sectional view of a CMOSFET 310 in accordance with the seventeenth exemplary embodiment of the present invention.

The CMOSFET 310 in accordance with the present exemplary embodiment is designed to include an n-channel type MOSFET 102C, and the p-channel type MOSFET 202 in accordance with the sixth exemplary embodiment, illustrated in FIG. 14.

The CMOSFET 310 in accordance with the present exemplary embodiment is structurally different from the CMOSFET 302 in accordance with the ninth exemplary embodiment, illustrated in FIG. 22G, in that the n-channel type MOSFET 102C is designed to include a fifth stress-having film 22 having tensile stress therein in place of the sixth stress-having film 12 having tensile compressive therein.

Specifically, the CMOSFET 310 in accordance with the present exemplary embodiment is designed to include an eighth stress-having film 14 having tensile stress therein, and covering both the fifth stress-having film 22 formed in the n-channel type MOSFET 102, and the seventh stress-having film 24 formed in the p-channel type MOSFET 202.

The CMOSFET 310 in accordance with the present exemplary embodiment is structurally identical with the CMOSFET 302 in accordance with the ninth exemplary embodiment, illustrated in FIG. 22G, except in that the n-channel type MOSFET 102C is designed to include the fifth stress-having film 22 in place of the sixth stress-having film 12. Accordingly, parts or elements that correspond to those of the CMOSFET 302 in accordance with the ninth exemplary embodiment have been provided with the same reference numerals, and are not explained hereinbelow.

Hereinbelow are explained the advantages provided by the CMOSFET 310 in accordance with the present exemplary embodiment.

In the CMOSFET 310 in accordance with the present exemplary embodiment, since the fifth stress-having film 22 having tensile stress therein is formed thick covering the gate electrode 7, the sidewall spacer 8, and the source/drain regions therewith, high tensile distortion is applied to a channel in the n-channel type MOSFET 102, resulting in significant enhancement in mobility of carriers (electrons) in the n-channel type MOSFET 102.

Furthermore, since the seventh stress-having film 24 having compressive stress is formed thick covering the gate electrode 7, the sidewall spacer 8, and the source/drain regions therewith, high compressive distortion is applied to a channel in the p-channel type MOSFET 202, resulting in significant enhancement in mobility of carriers (holes) in the p-channel type MOSFET 202.

Hereinbelow is explained a method of fabricating the CMOSFET 3108 in accordance with the present exemplary embodiment.

A method of fabricating the CMOSFET 310 in accordance with the present exemplary embodiment can be obtained by omitting both the step of removing the eighth stress-having film 14 having tensile stress therein, in a region in which the n-channel type MOSFET 102 is fabricated, and the step of forming the sixth stress-having film 12 having compressive stress, and removing the sixth stress-having film 12 in a region in which the p-channel type MOSFET 202 is fabricated, out of a method of fabricating the CMOSFET 302 in accordance with the ninth exemplary embodiment.

That is, a method of fabricating the CMOSFET 302 in accordance with the ninth exemplary embodiment has to include a plurality of steps to form the sixth stress-having film 12 and the eighth stress-having film 14. In contrast, a method of fabricating the CMOSFET 310 in accordance with the present exemplary embodiment makes it possible to reduce a number of steps, because there is only formed the eighth stress-having film 14.

In the CMOSFET 310 in accordance with the present exemplary embodiment, similarly to the n-channel type MOSFET 102A in accordance with the first variant of the third exemplary embodiment, illustrated in FIG. 10, the eighth stress-having film 14 may be formed only on the gate electrodes 7 in the p-channel type MOSFET 202. In the n-channel type MOSFET 102C, the eighth stress-having film 14 may be left as it is.

In the semiconductor device in accordance with the above-mentioned exemplary embodiments and the variants thereof, a gate electrode of an nMOSFET is partially comprised of an electrically conductive stress-having film having compressive stress, or a gate electrode of an nMOSFET is covered with a stress-having film having compressive stress. Furthermore, a gate electrode of a pMOSFET is partially comprised of an electrically conductive stress-having film having tensile stress, or a gate electrode of a pMOSFET is covered with a stress-having film having tensile stress.

Accordingly, stress to be applied to a channel region is no longer weakened by a stress-having film or an electrically conductive stress-having film, and hence, it is possible to apply high distortion to a channel of an nMOSFET or a pMOSFET.

Thus, the semiconductor device in accordance with the above-mentioned exemplary embodiments and the variants thereof makes it possible to enhance mobility of carriers, and hence, enhance performances of an nMOSFET and a pMOSFET.

While the present invention has been described in connection with certain exemplary embodiments, it is to be understood that the subject matter encompassed by way of the present invention is not to be limited to those specific embodiments. On the contrary, it is intended for the subject matter of the invention to include all alternatives, modifications and equivalents as can be included within the spirit and scope of the following claims.

This application is based upon and claims the benefit of priority from Japanese Patent Application No. 2005-273117 filed on Sep. 21, 2005, the entire disclosure of which, including specification, claims, drawings and summary, is incorporated herein by reference in its entirety.

1. A semiconductor device including an n-channel type MOSFET,
wherein said semiconductor device includes a first stress-having film being formed on a gate electrode of said n-channel type MOSFET, and locally having compressive stress.

2. A semiconductor device including a p-channel type MOSFET,
wherein said semiconductor device includes a second stress-having film being formed on a gate electrode of said p-channel type MOSFET, and locally having tensile stress.

3. A semiconductor device including an n-channel type MOSFET and a p-channel type MOSFET,
wherein said semiconductor device includes:
a first stress-having film being formed on a gate electrode of said n-channel type MOSFET, and locally having compressive stress; and
a second stress-having film being formed on a gate electrode of said p-channel type MOSFET, and locally having tensile stress.

4. The semiconductor device as set forth in claim 3, further comprising a third stress-having film covering said n-channel type MOSFET therewith, and having tensile stress.

5. The semiconductor device as set forth in claim 2, further comprising a fourth stress-having film covering said p-channel type MOSFET therewith, and having compressive stress.

6. A semiconductor device including an n-channel type MOSFET,
wherein said semiconductor device includes:
a first stress-having film being formed on a gate electrode of said n-channel type MOSFET, and having compressive stress; and
a third stress-having film being formed on source/drain regions of said n-channel type MOSFET, having almost the same height as that of said first stress-having film, and having tensile stress.

7. A semiconductor device including a p-channel type MOSFET,
wherein said semiconductor device includes:
a second stress-having film being formed on a gate electrode of said p-channel type MOSFET, and having tensile stress; and
a seventh stress-having film being formed on source/drain regions of said p-channel type MOSFET, having almost the same height as that of said second stress-having film, and having compressive stress.

8. A semiconductor device including an n-channel type MOSFET and a p-channel type MOSFET,
wherein said semiconductor device includes:
a first stress-having film being formed on a gate electrode of said n-channel type MOSFET, and having compressive stress;
a third stress-having film being formed on source/drain regions of said n-channel type MOSFET, having almost the same height as that of said first stress-having film, and having tensile stress;
a second stress-having film being formed on a gate electrode of said p-channel type MOSFET, and having tensile stress; and
a seventh stress-having film being formed on source/drain regions of said p-channel type MOSFET, having almost the same height as that of said second stress-having film, and having compressive stress.

9. A semiconductor device including an n-channel type MOSFET,
wherein said semiconductor device includes:
a fifth stress-having film being formed on source/drain regions of said n-channel type MOSFET, having almost the same height as that of a gate electrode of said n-channel type MOSFET, and having tensile stress; and
a sixth stress-having film being formed entirely on both a gate electrode of said n-channel type MOSFET and said fifth stress-having film, and having compressive stress.

10. A semiconductor device including a p-channel type MOSFET,
wherein said semiconductor device includes:
a seventh stress-having film being formed on source/drain regions of said p-channel type MOSFET, having almost the same height as that of a gate electrode of said p-channel type MOSFET, and having compressive stress; and
an eighth stress-having film being formed entirely on both a gate electrode of said p-channel type MOSFET and said seventh stress-having film, and having tensile stress.

11. A semiconductor device including an n-channel type MOSFET and a p-channel type MOSFET,
wherein said semiconductor device includes:
a fifth stress-having film being formed on source/drain regions of said n-channel type MOSFET, having almost the same height as that of a gate electrode of said n-channel type MOSFET, and having tensile stress;
a sixth stress-having film being formed entirely on both a gate electrode of said n-channel type MOSFET and said fifth stress-having film, and having compressive stress;
a seventh stress-having film being formed on source/drain regions of said p-channel type MOSFET, having almost the same height as that of a gate electrode of said p-channel type MOSFET, and having compressive stress; and
an eighth stress-having film being formed entirely on both a gate electrode of said p-channel type MOSFET and said seventh stress-having film, and having tensile stress.

12. A semiconductor device including an n-channel type MOSFET,
wherein said semiconductor device includes:
a fifth stress-having film being formed on source/drain regions of said n-channel type MOSFET, having almost the same height as that of a gate electrode of said n-channel type MOSFET, and having tensile stress; and
a sixth stress-having film being formed on a gate electrode of said n-channel type MOSFET, and having compressive stress.

13. A semiconductor device including a p-channel type MOSFET,
wherein said semiconductor device includes:
a seventh stress-having film being formed on source/drain regions of said p-channel type MOSFET, having almost the same height as that of a gate electrode of said p-channel type MOSFET, and having compressive stress; and
an eighth stress-having film being formed on a gate electrode of said p-channel type MOSFET, and having tensile stress.

14. A semiconductor device including an n-channel type MOSFET and a p-channel type MOSFET,
wherein said semiconductor device includes:
a fifth stress-having film being formed on source/drain regions of said n-channel type MOSFET, having almost the same height as that of a gate electrode of said n-channel type MOSFET, and having tensile stress;
a sixth stress-having film being formed on a gate electrode of said n-channel type MOSFET, and having compressive stress;
a seventh stress-having film being formed on source/drain regions of said p-channel type MOSFET, having almost the same height as that of a gate electrode of said p-channel type MOSFET, and having compressive stress; and
an eighth stress-having film being formed on a gate electrode of said p-channel type MOSFET, and having tensile stress.

15. A semiconductor device including an n-channel type MOSFET and a p-channel type MOSFET,
wherein said semiconductor device includes:
a first stress-having film being formed on a gate electrode of said n-channel type MOSFET, and locally having compressive stress;
a second stress-having film being formed on a gate electrode of said p-channel type MOSFET, and locally having tensile stress;
a third stress-having film covering said n-channel type MOSFET therewith, and having tensile stress; and
a fourth stress-having film covering said p-channel type MOSFET therewith, and having compressive stress.

16. A semiconductor device including an n-channel type MOSFET and a p-channel type MOSFET,
wherein said semiconductor device includes:
a first stress-having film being formed on both a gate electrode of said n-channel type MOSFET and a gate electrode of said p-channel type MOSFET, and locally having compressive stress;
a third stress-having film covering said n-channel type MOSFET therewith, and having tensile stress; and
a fourth stress-having film covering said p-channel type MOSFET therewith, and having compressive stress.

17. A semiconductor device including an n-channel type MOSFET and a p-channel type MOSFET,
wherein said semiconductor device includes:
a second stress-having film being formed on both a gate electrode of said n-channel type MOSFET and a gate electrode of said p-channel type MOSFET, and locally having tensile stress;
a third stress-having film covering said n-channel type MOSFET therewith, and having tensile stress; and
a fourth stress-having film covering said p-channel type MOSFET therewith, and having compressive stress.

18. A semiconductor device including an n-channel type MOSFET and a p-channel type MOSFET,
wherein said semiconductor device includes:
a first stress-having film being formed on a gate electrode of said n-channel type MOSFET, and locally having compressive stress;
a second stress-having film being formed on a gate electrode of said p-channel type MOSFET, and locally having tensile stress; and
a third stress-having film covering said n-channel type MOSFET and said p-channel type MOSFET therewith, and having tensile stress.

19. A semiconductor device including an n-channel type MOSFET and a p-channel type MOSFET,
wherein said semiconductor device includes:
a first stress-having film being formed on a gate electrode of said n-channel type MOSFET, and locally having compressive stress;
a second stress-having film being formed on a gate electrode of said p-channel type MOSFET, and locally having tensile stress; and
a fourth stress-having film covering said n-channel type MOSFET and said p-channel type MOSFET therewith, and having compressive stress.

20. The semiconductor device as set forth in claim 4, wherein said third stress-having film has a portion on said gate electrode in which stress is relaxed.

21. The semiconductor device as set forth in claim 4, wherein said third stress-having film is partially cut out on said gate electrode.

22. The semiconductor device as set forth in claim 4, wherein said third stress-having film covering source/drain regions of said n-channel type MOSFET has such a thickness that a surface of said third stress-having film is on a level with a surface of said first stress-having film.

23. A semiconductor device including an n-channel type MOSFET and a p-channel type MOSFET,
wherein said semiconductor device includes:
a fifth stress-having film being formed on both source/drain regions of said n-channel type MOSFET and source/drain regions of said p-channel type MOSFET, having almost the same height as that of gate electrodes of said n-channel type MOSFET and said p-channel type MOSFET, and having tensile stress;
a sixth stress-having film being formed on a gate electrode of said n-channel type MOSFET, and having compressive stress; and
an eighth stress-having film being formed on a gate electrode of said p-channel type MOSFET, and having tensile stress.

24. A semiconductor device including an n-channel type MOSFET and a p-channel type MOSFET,
wherein said semiconductor device includes:
a seventh stress-having film being formed on both source/drain regions of said n-channel type MOSFET and source/drain regions of said p-channel type MOSFET, having almost the same height as that of gate electrodes of said n-channel type MOSFET and said p-channel type MOSFET, and having compressive stress;
a sixth stress-having film being formed on a gate electrode of said n-channel type MOSFET, and having compressive stress; and
an eighth stress-having film being formed on a gate electrode of said p-channel type MOSFET, and having tensile stress.

25. A semiconductor device including an n-channel type MOSFET and a p-channel type MOSFET,
wherein said semiconductor device includes:
a fifth stress-having film being formed on source/drain regions of said n-channel type MOSFET, having almost the same height as that of a gate electrode of said n-channel type MOSFET, and having tensile stress;
a seventh stress-having film being formed on source/drain regions of said p-channel type MOSFET, having almost the same height as that of a gate electrode of said p-channel type MOSFET, and having compressive stress; and
one of a sixth stress-having film and an eighth stress-having film, said sixth stress-having film being formed on both a gate electrode of said n-channel type MOSFET and a gate electrode of said p-channel type MOSFET, and having compressive stress, said eighth stress-having film being formed on both a gate electrode of said n-channel type MOSFET and a gate electrode of said p-channel type MOSFET, and having tensile stress.

26. A semiconductor device including an n-channel type MOSFET and a p-channel type MOSFET,
wherein said semiconductor device includes:
a fifth stress-having film being formed on both source/drain regions of said n-channel type MOSFET and source/drain regions of said p-channel type MOSFET, having almost the same height as that of gate electrodes of said n-channel type MOSFET and said p-channel type MOSFET, and having tensile stress;
a sixth stress-having film covering said n-channel type MOSFET therewith and being formed on said fifth stress-having film, and having compressive stress; and
an eighth stress-having film covering said p-channel type MOSFET therewith and being formed on said fifth stress-having film, and having tensile stress.

27. A semiconductor device including an n-channel type MOSFET and a p-channel type MOSFET,
wherein said semiconductor device includes:
a seventh stress-having film being formed on both source/drain regions of said n-channel type MOSFET and source/drain regions of said p-channel type MOSFET, having almost the same height as that of gate electrodes of said n-channel type MOSFET and said p-channel type MOSFET, and having compressive stress;
a sixth stress-having film covering said n-channel type MOSFET therewith and being formed on said seventh stress-having film, and having compressive stress; and
an eighth stress-having film covering said p-channel type MOSFET therewith and being formed on said seventh stress-having film, and having tensile stress.

28. A semiconductor device including an n-channel type MOSFET and a p-channel type MOSFET,
wherein said semiconductor device includes:
a fifth stress-having film being formed on source/drain regions of said n-channel type MOSFET, having almost the same height as that of a gate electrode of said n-channel type MOSFET, and having tensile stress;
a seventh stress-having film being formed on source/drain regions of said p-channel type MOSFET, having almost the same height as that of a gate electrode of said p-channel type MOSFET, and having compressive stress;
one of a sixth stress-having film and an eighth stress-having film, said sixth stress-having film covering both said n-channel type MOSFET and said p-channel type MOSFET therewith and being formed on both said fifth stress-having film and said seventh stress-having film, and having compressive stress, said eighth stress-having film covering both said n-channel type MOSFET and said p-channel type MOSFET therewith and being formed on said fifth stress-having film and said seventh stress-having film, and having tensile stress.

29. The semiconductor device as set forth in claim 1, wherein said semiconductor device includes, in place of said first stress-having film, a first electrically conductive stress-having film being formed at least partially on a gate electrode of said n-channel type MOSFET, and having compressive stress.

30. The semiconductor device as set forth in claim 2, wherein said semiconductor device includes, in place of said second stress-having film, a second electrically conductive stress-having film being formed at least partially on a gate electrode of said p-channel type MOSFET, and having tensile stress.

31. The semiconductor device as set forth in claim 1, wherein each of said first, second, sixth and eighth stress-having film contains at least one of silicide of carbon, oxygen or nitrogen, hydrogenated silicide of carbon, oxygen or nitrogen, oxide of aluminum, hafnium, tantalum, zirconium or silicon, and nitrogenated oxide of aluminum, hafnium, tantalum, zirconium or silicon.

32. The semiconductor device as set forth in claim 1, wherein said first or second electrically conductive stress-having film contains at least one of silicide containing one of cobalt, nickel and titanium, tungsten, aluminum, copper, and platinum.

33. The semiconductor device as set forth in claim 1, wherein at least one of said n-channel type MOSFET and said p-channel type MOSFET is formed on a substrate composed of one of silicon containing silicon and germanium therein, and silicon containing carbon therein.

34. The semiconductor device as set forth in claim 3, further comprising a third stress-having film covering said n-channel type MOSFET therewith, and having tensile stress.

35. The semiconductor device as set forth in claim 3, further comprising a fourth stress-having film covering said p-channel type MOSFET therewith, and having compressive stress.

36. The semiconductor device as set forth in claim 15, wherein at least one of said third stress-having film and said fourth stress-having film has a portion on said gate electrode in which stress is relaxed.

37. The semiconductor device as set forth in claim 16, wherein at least one of said third stress-having film and said fourth stress-having film has a portion on said gate electrode in which stress is relaxed.

38. The semiconductor device as set forth in claim 17, wherein at least one of said third stress-having film and said fourth stress-having film has a portion on said gate electrode in which stress is relaxed.

39. The semiconductor device as set forth in claim 18, wherein at least one of said third stress-having film and said fourth stress-having film has a portion on said gate electrode in which stress is relaxed.

40. The semiconductor device as set forth in claim 19, wherein at least one of said third stress-having film and said fourth stress-having film has a portion on said gate electrode in which stress is relaxed.

41. The semiconductor device as set forth in claim 15, wherein at least one of said third stress-having film and said fourth stress-having film is partially cut out on said gate electrode.

42. The semiconductor device as set forth in claim 16, wherein at least one of said third stress-having film and said fourth stress-having film is partially cut out on said gate electrode.

43. The semiconductor device as set forth in claim 17, wherein at least one of said third stress-having film and said fourth stress-having film is partially cut out on said gate electrode.

44. The semiconductor device as set forth in claim 18, wherein at least one of said third stress-having film and said fourth stress-having film is partially cut out on said gate electrode.

45. The semiconductor device as set forth in claim 19, wherein at least one of said third stress-having film and said fourth stress-having film is partially cut out on said gate electrode.

46. The semiconductor device as set forth in claim 15, wherein said third stress-having film or said fourth stress-having film covering source/drain regions of said n-channel type MOSFET or said p-channel type MOSFET has such a thickness that a surface of said third stress-having film or said fourth stress-having film is on a level with a surface of said first stress-having film or said second stress-having film.

47. The semiconductor device as set forth in claim 16, wherein said third stress-having film or said fourth stress-having film covering source/drain regions of said n-channel type MOSFET or said p-channel type MOSFET has such a thickness that a surface of said third stress-having film or said fourth stress-having film is on a level with a surface of said first stress-having film or said second stress-having film.

48. The semiconductor device as set forth in claim 17, wherein said third stress-having film or said fourth stress-having film covering source/drain regions of said n-channel type MOSFET or said p-channel type MOSFET has such a thickness that a surface of said third stress-having film or said fourth stress-having film is on a level with a surface of said first stress-having film or said second stress-having film.

49. The semiconductor device as set forth in claim 18, wherein said third stress-having film or said fourth stress-having film covering source/drain regions of said n-channel type MOSFET or said p-channel type MOSFET has such a thickness that a surface of said third stress-having film or said fourth stress-having film is on a level with a surface of said first stress-having film or said second stress-having film.

50. The semiconductor device as set forth in claim 19, wherein said third stress-having film or said fourth stress-having film covering source/drain regions of said n-channel type MOSFET or said p-channel type MOSFET has such a thickness that a surface of said third stress-having film or said fourth stress-having film is on a level with a surface of said first stress-having film or said second stress-having film.

51. The semiconductor device as set forth in claim 3, wherein said semiconductor device includes, in place of said first stress-having film, a first electrically conductive stress-having film being formed at least partially on a gate electrode of said n-channel type MOSFET, and having compressive stress.

52. The semiconductor device as set forth in claim 15, wherein said semiconductor device includes, in place of said first stress-having film, a first electrically conductive stress-having film being formed at least partially on a gate electrode of said n-channel type MOSFET, and having compressive stress.

53. The semiconductor device as set forth in claim 16, wherein said semiconductor device includes, in place of said first stress-having film, a first electrically conductive stress-having film being formed at least partially on a gate electrode of said n-channel type MOSFET, and having compressive stress.

54. The semiconductor device as set forth in claim 18, wherein said semiconductor device includes, in place of said first stress-having film, a first electrically conductive stress-having film being formed at least partially on a gate electrode of said n-channel type MOSFET, and having compressive stress.

55. The semiconductor device as set forth in claim 19, wherein said semiconductor device includes, in place of said first stress-having film, a first electrically conductive stress-having film being formed at least partially on a gate electrode of said n-channel type MOSFET, and having compressive stress.

56. The semiconductor device as set forth in claim 3, wherein said semiconductor device includes, in place of said second stress-having film, a second electrically conductive stress-having film being formed at least partially on a gate electrode of said p-channel type MOSFET, and having tensile stress.

57. The semiconductor device as set forth in claim 15, wherein said semiconductor device includes, in place of said second stress-having film, a second electrically conductive stress-having film being formed at least partially on a gate electrode of said p-channel type MOSFET, and having tensile stress.

58. The semiconductor device as set forth in claim 17, wherein said semiconductor device includes, in place of said second stress-having film, a second electrically conductive stress-having film being formed at least partially on a gate electrode of said p-channel type MOSFET, and having tensile stress.

59. The semiconductor device as set forth in claim 18, wherein said semiconductor device includes, in place of said second stress-having film, a second electrically conductive stress-having film being formed at least partially on a gate electrode of said p-channel type MOSFET, and having tensile stress.

60. The semiconductor device as set forth in claim 19, wherein said semiconductor device includes, in place of said second stress-having film, a second electrically conductive stress-having film being formed at least partially on a gate electrode of said p-channel type MOSFET, and having tensile stress.

61. The semiconductor device as set forth in claim 5, wherein said fourth stress-having film has a portion on said gate electrode in which stress is relaxed.

62. The semiconductor device as set forth in claim 5, wherein said fourth-stress having film is partially cut out on said gate electrode.

63. The semiconductor device as set forth in claim 5, wherein said fourth-stress having film covering source/drain regions of said p-channel type MOSFET has such a thickness that a surface of said fourth stress-having film is on a level with a surface of said second stress-having film.
